(19) United States
(12) Patent Application Publication
(10) Pub. No.: US 2025/0038546 A1
(43) Pub. Date: Jan. 30, 2025

(54) BATTERY CHARGING AND DISCHARGING BASED ON BATTERY CHARGE AND DISCHARGE PROFILES

(71) Applicants: Adam Gleason, Draper, UT (US); Manti Gleason, Draper, UT (US)

(72) Inventors: Adam Gleason, Draper, UT (US); Manti Gleason, Draper, UT (US)

(21) Appl. No.: 18/915,172

(22) Filed: Oct. 14, 2024

Related U.S. Application Data
(63) Continuation-in-part of application No. 18/766,452, filed on Jul. 8, 2024.
(60) Provisional application No. 63/589,815, filed on Oct. 12, 2023.
(60) Provisional application No. 63/512,585, filed on Jul. 7, 2023.

(51) Int. Cl. H02J 7/00; G01R 31/3835

(52) U.S. Cl. CPC H02J 7/00032; G01R 31/3835; H02J 7/0013; H02J 7/0042; H02J 7/00712; H02J 7/007188

(57) ABSTRACT

Examples of the present disclosure include the method. The method includes receiving a battery in a slot. The battery is removable from the slot to power a device separate from the slot. The method includes determining a profile for the battery. The profile includes at least one of a charging parameter based at least in part on a charging priority for the battery, a discharging parameter based at least in part on a discharging priority for the battery, or a combination thereof. The method includes initiating at least one of a charge cycle to charge the battery based at least in part on the charging parameter while the battery is received by the slot and a discharge cycle to discharge the battery based at least in part on the discharging parameter while the battery is received by the slot.

### CROSS-REFERENCES TO RELATED APPLICATIONS

This application is a continuation-in-part of U.S. patent application Ser. No. 18/766,452, entitled “SYSTEM, APPARATUS, AND METHOD FOR DETERMINING BATTERY STATE OF HEALTH” and filed on Jul. 8, 2024, which claims the benefit of U.S. Provisional Patent Application No. 63/512,585, both of which are incorporated herein by reference. This application also claims the benefit of U.S. Provisional Patent Application No. 63/589,815, entitled “BATTERY CHARGING AND DISCHARGING BASED ON BATTERY CHARGE AND DISCHARGE PROFILES,” which is incorporated herein by reference.

### GOVERNMENT RIGHTS

This invention was made with government support under Contract No. FA864922P1066 awarded by the U.S. Air Force. The government has certain rights in the invention.

### FIELD

This invention relates to battery charging and discharging and more particularly relates to charging and discharging batteries based on battery charge and discharge profiles.

### BACKGROUND

Batteries provide power to devices in numerous industries and applications, including electric aircraft, robotics, automated equipment, and electric vehicles. Batteries are charged in preparation to power such devices. Many electric aircraft and electric vehicles are powered by multiple batteries.

### SUMMARY

Examples of the present disclosure include the method. The method includes receiving a battery in a slot. The battery is removable from the slot to power a device separate from the slot. The method includes determining a profile for the battery. The profile includes at least one of a charging parameter based at least in part on a charging priority for the battery, a discharging parameter based at least in part on a discharging priority for the battery, or a combination thereof. The method includes initiating at least one of a charge cycle to charge the battery based at least in part on the charging parameter while the battery is received by the slot and a discharge cycle to discharge the battery based at least in part on the discharging parameter while the battery is received by the slot.

Examples of the present disclosure include a system. The system includes a slot configured to receive a battery. The battery is removable from the slot to power a device, the device being separate from the slot. The system includes a memory and a processor coupled with the memory and configured to cause the system to determine a profile for the battery. The profile includes at least one of a charging parameter based at least in part on a charging priority for the battery, a discharging parameter based at least in part on a discharging priority for the battery, or a combination thereof. The processor is further configured to cause the system to initiate at least one of a charge cycle to charge the battery based at least in part on the charging parameter while the battery is received by the slot and a discharge cycle to discharge the battery based at least in part on the discharging parameter while the battery is received by the slot.

Examples of the present disclosure include an apparatus. The apparatus includes a priorities module configured to determine and/or receive: a charging priority for a battery, a discharging priority for the battery, or a combination thereof. The apparatus includes a profile module configured to determine a profile for the battery, the profile comprising at least one of a charging parameter based at least in part on the charging priority for the battery, a discharging parameter based at least in part on the discharging priority for the battery, or a combination thereof. The apparatus includes a charge cycle module configured to initiate at least one of the following while the battery is received by a slot from which the battery is removable to power a device separate from the slot: a charge cycle to charge the battery based at least in part on the charging parameter and a discharge cycle to discharge the battery based at least in part on the discharging parameter while the battery is received by the slot. At least a portion of said modules comprise one or more of hardware circuits, programmable hardware circuits and executable code, the executable code stored on one or more computer readable storage media.

### BRIEF DESCRIPTION OF THE DRAWINGS

In order that the advantages of the invention will be readily understood, a more particular description of the invention briefly described above will be rendered by reference to specific examples that are illustrated in the appended drawings. Understanding that these drawings depict only typical examples of the invention and are not therefore to be considered to be limiting of its scope, the invention will be described and explained with additional specificity and detail through the use of the accompanying drawings, in which:

FIG. 1 is a schematic diagram illustrating one example of a system for charging, and discharging a battery;

FIG. 2 is a schematic diagram illustrating one example of a system for discharging a battery into a load;

FIG. 3 is a schematic diagram illustrating one example of a system for discharging a battery into another battery;

FIG. 4 is a schematic diagram illustrating one example of a device powered by multiple batteries;

FIG. 5 is a schematic block diagram illustrating one example of an apparatus for charging a battery;

FIG. 6 is a schematic block diagram illustrating another example of an apparatus for charging a battery;

FIG. 7 is a schematic flow chart diagram illustrating one example of a method for charging a battery based at least in part on a battery charge profile;

FIG. 8 is a schematic flow chart diagram illustrating one example of a method for discharging a battery based at least in part on an operational metric;

FIG. 9 is an illustration of voltage of a battery 106 over time while the battery is in use in the device, according to one or more examples of the present disclosure;

FIG. 10A is an external view of one example of an enclosure housing a charging apparatus; and

FIG. 10B is an internal view of one example of an enclosure housing a charging apparatus.

### DETAILED DESCRIPTION

Reference throughout this specification to “one example,” “an example,” or similar language means that a particular feature, structure, or characteristic described in connection with the example is included in at least one example. Thus, appearances of the phrases “in one example,” “in an example,” and similar language throughout this specification may, but do not necessarily, all refer to the same example, but mean “one or more but not all examples” unless expressly specified otherwise. The terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise.

Furthermore, the described features, structures, or characteristics of the invention may be combined in any suitable manner in one or more examples. In the following description, numerous specific details are provided, such as examples of programming, software modules, user selections, network transactions, database queries, database structures, hardware modules, hardware circuits, hardware chips, etc., to provide a thorough understanding of examples of the invention. One skilled in the relevant art will recognize, however, that the invention may be practiced without one or more of the specific details, or with other methods, components, materials, and so forth. In other instances, well-known structures, materials, or operations are not shown or described in detail to avoid obscuring aspects of the invention.

The schematic flow chart diagrams included herein are generally set forth as logical flow chart diagrams. As such, the depicted order and labeled steps are indicative of one example of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

Reference throughout this specification to “one example,” “an example,” or similar language means that a particular feature, structure, or characteristic described in connection with the example is included in at least one example. Thus, appearances of the phrases “in one example,” “in an example,” and similar language throughout this specification may, but do not necessarily, all refer to the same example, but mean “one or more but not all examples” unless expressly specified otherwise. The terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise.

Furthermore, the described features, advantages, and characteristics of the examples may be combined in any suitable manner. One skilled in the relevant art will recognize that the examples may be practiced without one or more of the specific features or advantages of a particular example. In other instances, additional features and advantages may be recognized in certain examples that may not be present in all examples.

These features and advantages of the examples will become more fully apparent from the following description and appended claims, or may be learned by the practice of examples as set forth hereinafter. As will be appreciated by one skilled in the art, aspects of the present invention may be embodied as a system, method, and/or computer program product. Accordingly, aspects of the present invention may take the form of an entirely hardware example, an entirely software example (including firmware, resident software, micro-code, etc.) or an example combining software and hardware aspects that may all generally be referred to herein as a “circuit,” “module,” or “system.” Furthermore, aspects of the present invention may take the form of a computer program product embodied in one or more computer readable medium(s) having program code embodied thereon.

Many of the functional units described in this specification have been labeled as modules, in order to more particularly emphasize their implementation independence. For example, a module may be implemented as a hardware circuit comprising custom very large scale integrated (“VLSI”) circuits or gate arrays, off-the-shelf semiconductors such as logic chips, transistors, or other discrete components. A module may also be implemented in programmable hardware devices such as a field programmable gate array (“FPGA”), programmable array logic, programmable logic devices or the like.

Modules may also be implemented in software for execution by various types of processors. An identified module of program code may, for instance, comprise one or more physical or logical blocks of computer instructions which may, for instance, be organized as an object, procedure, or function. Nevertheless, the executables of an identified module need not be physically located together, but may comprise disparate instructions stored in different locations which, when joined logically together, comprise the module and achieve the stated purpose for the module.

Indeed, a module of program code may be a single instruction, or many instructions, and may even be distributed over several different code segments, among different programs, and across several memory devices. Similarly, operational data may be identified and illustrated herein within modules, and may be embodied in any suitable form and organized within any suitable type of data structure. The operational data may be collected as a single data set, or may be distributed over different locations including over different storage devices, and may exist, at least partially, merely as electronic signals on a system or network. Where a module or portions of a module are implemented in software, the program code may be stored and/or propagated on in one or more computer readable medium(s).

The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (“RAM”), a read-only memory (“ROM”), an erasable programmable read-only memory (“EPROM” or Flash memory), a static random access memory (“SRAM”), a portable compact disc read-only memory (“CD-ROM”), a digital versatile disk (“DVD”), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (“ISA”) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (“LAN”) or a wide area network (“WAN”), or the connection may be made to an external computer (for example, through the Internet using an Internet Service Provider). In some examples, electronic circuitry including, for example, programmable logic circuitry, field-programmable gate arrays (“FPGA”), or programmable logic arrays (“PLA”) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to examples of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

Many of the functional units described in this specification have been labeled as modules, in order to more particularly emphasize their implementation independence. For example, a module may be implemented as a hardware circuit comprising custom VLSI circuits or gate arrays, off-the-shelf semiconductors such as logic chips, transistors, or other discrete components. A module may also be implemented in programmable hardware devices such as field programmable gate arrays, programmable array logic, programmable logic devices or the like.

Modules may also be implemented in software for execution by various types of processors. An identified module of program instructions may, for instance, comprise one or more physical or logical blocks of computer instructions which may, for instance, be organized as an object, procedure, or function. Nevertheless, the executables of an identified module need not be physically located together, but may comprise disparate instructions stored in different locations which, when joined logically together, comprise the module and achieve the stated purpose for the module.

The schematic flowchart diagrams and/or schematic block diagrams in the Figures illustrate the architecture, functionality, and operation of possible implementations of apparatuses, systems, methods and computer program products according to various examples of the present invention. In this regard, each block in the schematic flowchart diagrams and/or schematic block diagrams may represent a module, segment, or portion of code, which comprises one or more executable instructions of the program code for implementing the specified logical function(s).

It should also be noted that, in some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. Other steps and methods may be conceived that are equivalent in function, logic, or effect to one or more blocks, or portions thereof, of the illustrated Figures.

Although various arrow types and line types may be employed in the flowchart and/or block diagrams, they are understood not to limit the scope of the corresponding examples. Indeed, some arrows or other connectors may be used to indicate only the logical flow of the depicted example. For instance, an arrow may indicate a waiting or monitoring period of unspecified duration between enumerated steps of the depicted example. It will also be noted that each block of the block diagrams and/or flowchart diagrams, and combinations of blocks in the block diagrams and/or flowchart diagrams, can be implemented by special purpose hardware-based systems that perform the specified functions or acts, or combinations of special purpose hardware and program code.

As used herein, a list with a conjunction of “and/or” includes any single item in the list or a combination of items in the list. For example, a list of A, B and/or C includes only A, only B, only C, a combination of A and B, a combination of B and C, a combination of A and C or a combination of A, B and C. As used herein, a list using the terminology “one or more of” includes any single item in the list or a combination of items in the list. For example, one or more of A, B and C includes only A, only B, only C, a combination of A and B, a combination of B and C, a combination of A and C or a combination of A, B and C. As used herein, a list using the terminology “one of” includes one and only one of any single item in the list. For example, “one of A, B and C” includes only A, only B or only C and excludes combinations of A, B and C. As used herein, “a member selected from the group consisting of A, B, and C,” includes one and only one of A, B, or C, and excludes combinations of A, B, and C. As used herein, “a member selected from the group consisting of A, B, and C and combinations thereof” includes only A, only B, only C, a combination of A and B, a combination of B and C, a combination of A and C or a combination of A, B and C.

Examples of the present disclosure include the method. The method includes receiving a battery in a slot. The battery is removable from the slot to power a device separate from the slot. The method includes determining a profile for the battery. The profile includes at least one of a charging parameter based at least in part on a charging priority for the battery, a discharging parameter based at least in part on a discharging priority for the battery, or a combination thereof. The method includes initiating at least one of a charge cycle to charge the battery based at least in part on the charging parameter while the battery is received by the slot and a discharge cycle to discharge the battery based at least in part on the discharging parameter while the battery is received by the slot.

In some examples, the method includes receiving and/or determining a future condition for the battery and determining the profile further based at least in part on the future condition. In some examples, the future condition includes a future time of operation for the battery. The method includes receiving, during the charge cycle, a modification to the future time of operation and updating, during the charge cycle, the profile based at least in part on the modification. The future condition includes a predicted operational condition of the battery, and the method further includes predicting the operational condition of the battery based at least in part on at least one of the following: user input, a previous operational condition of the battery, or any combination thereof. In some examples, the future condition includes at least one of: a future time of operation of the battery, a characteristic of an additional battery selected to be grouped with the battery for future operation, a life expectancy of the battery, an end of a rental period for the apparatus, a predicted future cost of charging the battery, a predicted future return on investment of the battery, or any combination thereof.

In some examples, the method includes determining the profile based at least in part on a characteristic of the battery, a characteristic of an additional battery grouped with the battery, or any combination thereof. In some examples, determining the profile includes selecting the profile from among one or more profiles.

In some examples, the method includes reading data from the battery. At least one of the charging parameter and the discharging parameter is further based on the data.

In some examples, the slot includes a slot of a plurality of slots of a charging apparatus. The method further includes determining an additional profile for an additional battery. The additional profile includes at least one of an additional charging parameter, an additional discharging parameter, or a combination thereof. The method includes initiating at least one of the following while the additional battery is received by an additional slot of the plurality of slots: an additional charge cycle to charge the additional battery based at least in part on the additional charging parameter and an additional discharge cycle to discharge the additional battery based at least in part on the additional discharging parameter. In some examples, a time period of the at least one of the additional charge cycle and the additional discharge cycle at least partially overlaps a time period of the at least one of the charge cycle and the discharge cycle.

In some examples, the charging parameter includes at least one of: a rate of charge, a final state of charge, length of charge, charging schedule, length of time for the battery to be connected to the slot, ambient temperature of the slot, temperature of the battery, or any combination thereof.

In some examples, the method includes assigning the battery and an additional battery to a group. The method includes determining a group profile. The group profile includes a group parameter based at least in part on at least one of: a future condition of the battery, a future condition of the additional battery, an attribute of the additional battery, or any combination thereof. The method includes determining whether to override the profile with the group profile. The method includes initiating, in response to determining to override the profile with the group profile, at least one of: an additional charge cycle to charge the battery based at least in part on the group parameter; an additional discharge cycle to discharge the battery based at least in part on the group parameter; an adjustment to the charge cycle to charge the battery based at least in part on the group parameter; an adjustment to the discharge cycle to discharge the battery based at least in part on the group parameter; or any combination thereof.

In some examples, the method includes receiving information about the battery from a battery management system and determining, based at least in part on the information, at least one of: the profile, the charging parameter, the charging priority, the discharging parameter, the discharging priority, or any combination thereof.

In some examples, the method includes initiating an additional discharge cycle to discharge an additional battery into the battery based at least in part on the charging parameter. The charging parameter includes a goal state of charge (“SoC”) of the battery. The method includes measuring an SoC of the battery and determining that the measured SoC is less than the goal SoC. Initiating the additional discharge cycle to discharge the additional battery into the battery is in response to determining that the measured SoC is less than the goal SoC.

Examples of the present disclosure include a system. The system includes a slot configured to receive a battery. The battery is removable from the slot to power a device, the device being separate from the slot. The system includes a memory and a processor coupled with the memory and configured to cause the system to determine a profile for the battery. The profile includes at least one of a charging parameter based at least in part on a charging priority for the battery, a discharging parameter based at least in part on a discharging priority for the battery, or a combination thereof. The processor is further configured to cause the system to initiate at least one of a charge cycle to charge the battery based at least in part on the charging parameter while the battery is received by the slot and a discharge cycle to discharge the battery based at least in part on the discharging parameter while the battery is received by the slot.

In some examples, at least one of the charging priority and the discharging priority include at least one of the following: long-term state of health (“SoH”) of the battery, battery performance, battery return on investment (“ROI”), ROI of the system, battery availability for use at a given time, compatibility with a source supplying power to a circuit used to actuate the charge and/or discharge cycle, atmospheric emissions resulting from charging, atmospheric emissions resulting from discharging, or any combination thereof.

Examples of the present disclosure include an apparatus. The apparatus includes a priorities module configured to determine and/or receive: a charging priority for a battery, a discharging priority for the battery, or a combination thereof. The apparatus includes a profile module configured to determine a profile for the battery, the profile comprising at least one of a charging parameter based at least in part on the charging priority for the battery, a discharging parameter based at least in part on the discharging priority for the battery, or a combination thereof. The apparatus includes a charge cycle module configured to initiate at least one of the following while the battery is received by a slot from which the battery is removable to power a device separate from the slot: a charge cycle to charge the battery based at least in part on the charging parameter and a discharge cycle to discharge the battery based at least in part on the discharging parameter while the battery is received by the slot. At least a portion of said modules comprise one or more of hardware circuits, programmable hardware circuits and executable code, the executable code stored on one or more computer readable storage media.

In some examples, the profile module is further configured to predict a future operational condition for the battery and determine the discharging parameter to mimic the predicted future operational condition. In some examples, the discharging parameter includes at least one of: a discharge rate, a final state of charge, an environmental condition of the slot, a temperature of the battery, a discharge schedule, or any combination thereof.

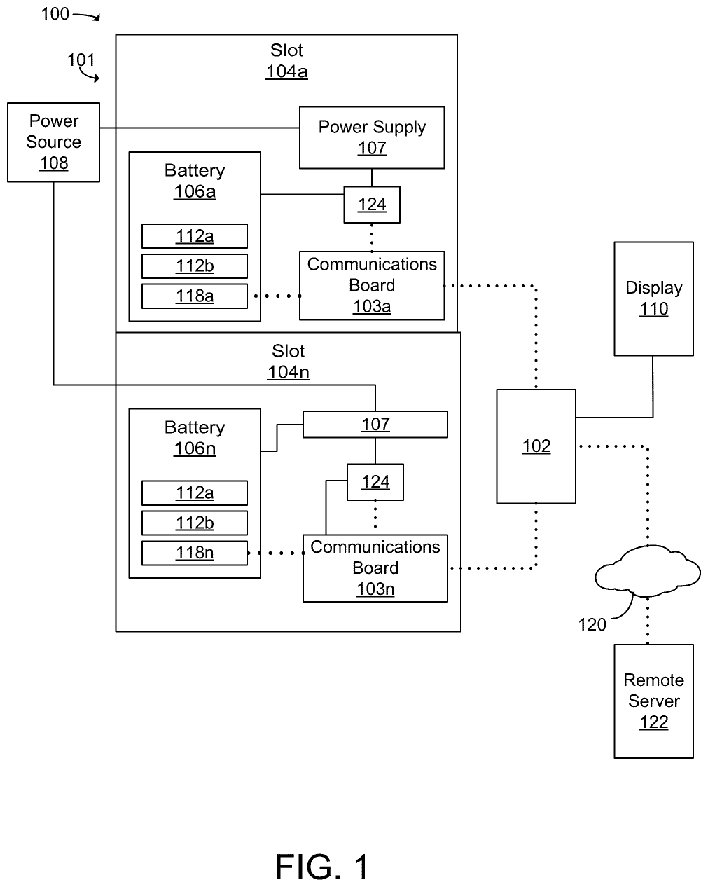

FIG. 1 is a schematic diagram illustrating one example of a system 100 for charging a battery 106a, . . . , 106n (which may be referred to herein, individually and/or collectively, as “106”). As shown in FIG. 1, the system 100 includes a number of batteries 106, a number of slots 104a, . . . , 104n (which may be referred to herein, individually or collectively, as “104”), a power source 108, a number of power supplies 107, a number of communications boards 103, a number of switches 124, a local processor 102, a display 110, and a remote server 122 connected to the communications board 103 and/or to the local processor 102 via a network 120.

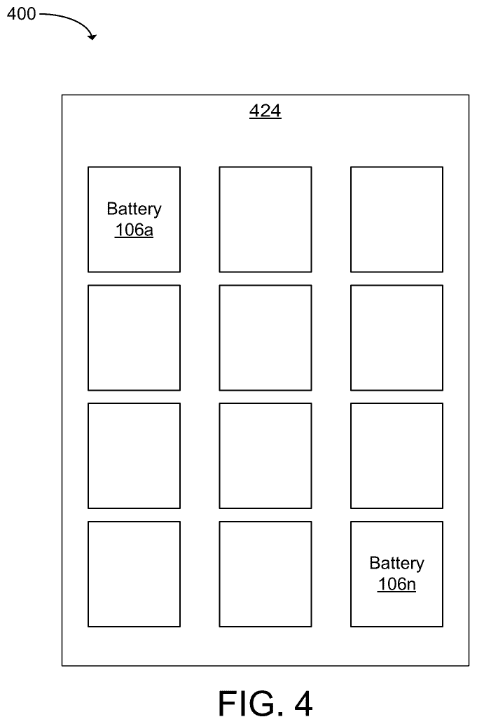

As shown in FIG. 1, the system 100 includes a charging apparatus 101 having a plurality of slots 104. As referred to herein, a “charging apparatus” includes, but is not limited to, the slots 104, communications boards 103, switches 124, power supplies 107, charger boards 105, display 110, and/or local processor 102. Each slot 104 is configured to receive at least one of the number of batteries 106. As used herein, “slot” refers to a portion, bay, chamber, and/or slot of the charging apparatus 101. The batteries 106 are rechargeable batteries that are removable from the slots 104 to power a device other than the charging apparatus 101. For example, the batteries 106 are removable from the slots 104 to power the device 424 of FIG. 4.

In some examples, the device 424 includes at least one of the following: a vehicle, an aircraft, an unmanned aerial vehicle (“UAV”), an electric aircraft, a battery energy storage system, and/or any combination thereof. The device 424 is a device 424 that is powered by replaceable batteries 106. In some examples, a first set of batteries 106 powers a device for a first operational cycle, and a different set of batteries 106 powers the device 424 for a subsequent operational cycle. For example, the device 424 is an aircraft, and the device 424 uses a first set of batteries 106 for a first flight and a second set of batteries 106 for a second flight while the first set is being charged by the charging apparatus 101. In some examples, the device 424 is a battery energy storage system, and the batteries 106, as part of the battery energy storage system, are configured to store energy and provide power to the grid (e.g., during period of high demand). In some examples, the batteries 106 are configured to store energy and provide backup power to a particular device and/or to the grid in case of a power supply issue and/or power outage. In some examples, the batteries 106 are lithium-ion batteries.

The system 100 includes a number of communications boards 103 and a remote server 122. As shown in FIG. 1, in some examples, the communications board 103 communicates indirectly with the remote server 122 via a local processor 102, which is connected to the remote server 122 through the network 120. In other examples, the communications board 103 is communicably connected directly to the remote server 122 via the network 120. In some examples, the system 100 does not include a local processor 102. In some examples, the remote server 122 is configured to perform any of the functions described herein in connection with the local processor 102. In some examples, the local processor 102 is configured to perform any of the functions as described herein in connection with the remote server 122. In various examples, the system 100 includes the local processor 102 but does not include the remote server 122. In such examples, the local processor 102 may or may not be connected to a network 120.

The system 100 is configured to run a charge cycle for the battery 106 by directing current into the battery 106 to charge the battery 106. As used herein, the term “charge cycle” refers to a period of time during which a battery is charged to any degree. As such, the term “charge cycle” as used herein is not limited to charging the battery to its full state of charge (“SoC”). As discussed herein, in some examples, the term “charge cycle” refers to a period of time during which a battery is charged to a SoC level that is based on user input and/or on a battery charge profile. In other examples, the length of time of the charge cycle is dependent on a length of time determined based on user input and/or a battery charge profile, rather than on a desired SoC level. In some examples, once the battery 106 is sufficiently charged to be used in the device, the battery 106 is removed from the slot 104 and received by the device 424.

In some examples, the slot 104 receives the battery 106, and the system 100 begins the charge cycle after the battery 106 is placed within the slot 104. In some examples, the charge cycle is initiated based on, for example, a battery charge profile, a user input, a charging schedule, and/or automatically upon sensing that the battery 106 has been placed in the slot 104. In some examples, the communications board 103 initiates the charge cycle in response to communication from at least one of the local processor 102, the remote server 122, and/or a remote computing device. For example, the communications board 103 initiates the charge cycle by instructing the power supply 107 to initiate flow of current to the battery 106 and/or by instructing the charger board 105 to allow flow of current from the power supply 107 to the battery 106. During the charge cycle, current flows from a power supply 107 into the battery 106 (e.g., through the charger board 105 directing current to the battery 106). Each of the power supplies 107 is powered by a power source 108.

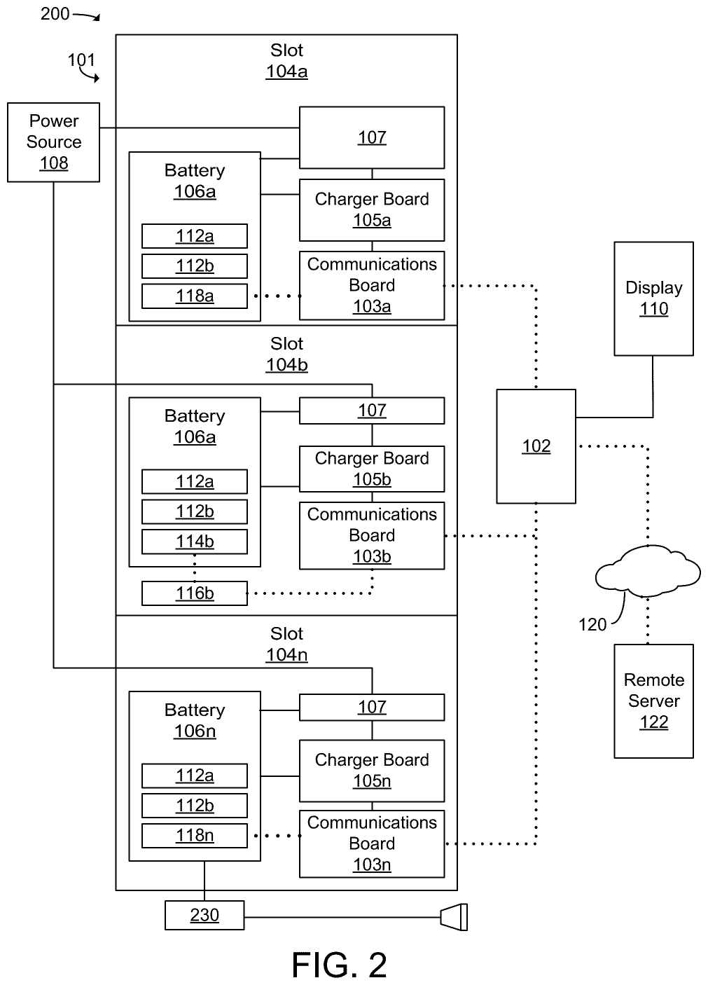

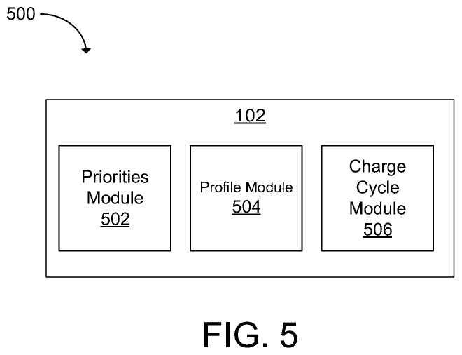

FIG. 5 is a schematic block diagram of an apparatus 500 for charging a battery 106, according to various examples. In some examples, the apparatus 500 includes a local processor 102 as shown in FIGS. 1 and 2. The apparatus 500 includes a priorities module 502, a profile module 504, and a charge cycle module 506, which are described below. In some examples, all or a portion of the apparatus 500 is implemented with executable code stored on computer readable storage media. In other examples, at least a portion of the apparatus 500 is implemented using hardware circuits and/or a programmable hardware device. In some examples, the modules of the apparatus 500 are housed in at least one of: the local processor 102, the remote server 122, a client device, another processor, and/or any combination thereof.

The apparatus 500 includes a priorities module 502 configured to receive and/or determine: a charging priority for a battery 106, a discharging priority for a battery 106, or a combination thereof. Priorities include, but are not limited to: long-term battery SoH, battery performance, battery availability, battery 106 return on investment (“ROI”), system 100 ROI, power source compatibility, environmental impact, system 100 power, mission-specific parameters, or any combination thereof. In some examples, the priorities module 502 is configured to determine the battery charge preference and/or priority based at least in part on: user input, inferred user preferences, a quantity of the batteries 106, and a future operation time.

The apparatus 500 includes a profile module 504 configured to determine a profile for the battery 106. In some examples, the profile includes a charging parameter based on at least in part on the charging priority for the battery 106. In some examples, the profile includes a discharging parameter based at least in part on the discharging priority for the battery. In some examples, the profile includes one or more charging parameters. In some examples, the apparatus 101 charges the battery 106 and/or discharges the battery 106 based at least in part on the profile. As used herein, “profile” refers to one or more parameters for charging and/or discharging the battery 106 and/or a set of instructions to the apparatus 101 for charging and/or discharging the battery 106. In some examples, the profile dictates charging parameters for a particular charge cycle. In some examples, the profile also dictates the timing and frequency for charge cycles.

Charging parameters include, but are not limited to: a rate of charge, a charging schedule (e.g., a start time/date and/or a stop time/date of the charge cycle), a final level of charge (SoC) at the end of the charge cycle, length of time of the charge cycle, total power consumption through the charge cycle, ambient temperature of the battery's 106 environment during the charge cycle, a frequency of current adjustment within the charge cycle, or any combination thereof.

In some examples, a multitude of charge profiles are stored in a memory (e.g., a memory of the apparatus 500). In some examples, the profile module 504 is configured to select the charge profile for an individual battery 106. In other examples, the profile module 504 is configured to select the charge profile for a group of batteries 106, and the charging parameters are applied to each of the batteries 106 during the charge cycle.

In some examples, the apparatus 500 includes a charge cycle module 506 that is configured to initiate at least one of: a charge cycle to charge the battery based at least in part on the charging parameter and a discharge cycle to discharge the battery based at least in part on the discharging parameter. In some examples, the charge cycle module 506 is configured to actuate a circuit, such as the communications board 103 and/or the charger board 105, to direct power to each battery slot 104 of the plurality of battery slots 104 to charge a battery 106 received by the battery slot 104 in a charge cycle based at least in part on the battery charge profile selected by the profile module 504. As referred to herein, a “circuit” may include, but is not limited to, the charger board 105, the communications board 103, the switch 124, and/or any combination thereof. In some examples, the charge cycle module 506 is configured to communicate the charging parameters of the charge profile to the communications board 103 during and/or before the charge cycle. The communications board 103 implements the charging parameters for the charge cycle (via, for example, the charger board 105 and/or the power supply 107.

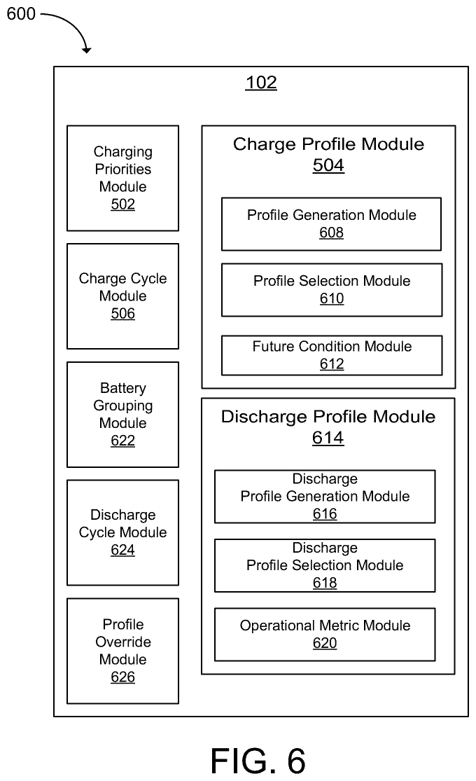

FIG. 6 is a schematic block diagram of another example of an apparatus 600 for charging and/or discharging a battery 106. The apparatus 600 is an example of the apparatus 500 of FIG. 5. In some examples, the apparatus 600 includes a priorities module 502, a profile module 504, and a charge cycle module 506. In some examples, the apparatus 600 includes at least one of a profile generation module 608, a profile selection module 610, a future condition module 612, a discharge profile module 614, a discharge profile generation module 616, a discharge profile selection module 618, an operational metric module 620, a battery grouping module 622, and/or a discharge cycle module 624. In some examples, the apparatus 500 includes a local processor 102. In some examples, all or a portion of the apparatus 500 is implemented with executable code stored on computer readable storage media. In other examples, at least a portion of the apparatus 500 is implemented using hardware circuits and/or a programmable hardware device.

“Determining” a charge profile, in some examples, includes selecting a charge profile from among a multitude of generated charge profiles. In other examples, “determining” a charge profile includes generating a custom charge profile. As such, in some examples, the profile module 504 includes a profile selection module 610 that is configured to select a charge profile from one or more charge profiles. In some examples, the profile module 504 also includes a profile generation module 608 configured to build a charge profile based on a battery charge preference and/or priority.

For example, charging a battery 106 at a fast rate will make the battery 106 available for use at an earlier time, but a slower charging rate may be optimal to preserve the long-term SoH of the battery 106. As such, the priorities module 502 is configured to determine whether to prioritize long-term SoH or battery availability. In response to that determination, the profile selection module 610 is configured to select a charge profile accordingly. For example, the system 100 receives input from a user (e.g., via a GUI of the display 110) indicating that the battery 106 is needed for an operation within a short time frame, such as one hour. Given the short time frame, the profile selection module 610 selects a battery availability charge profile that includes charging parameters to ensure that the battery 106 is available and sufficiently charged within the hour.

In some examples, the profile selection module 610 is configured to select the battery charge profile based on user input. For example, the user directly selects the battery charge profile. In another example, the user inputs priorities or preferences. The priorities module 502 transmits those inputs to the profile module 504, and the profile generation module 608 and/or the profile selection module 610 generates and/or selects the charge profile based on the user's input. User input is received, for example: via a GUI of the display 110, via another external input device in communication with the local processor 102 (e.g., a mouse, keyboard, microphone, etc.), via a remote computing device in communication with the system 100 (e.g., a mobile device or computer), from the remote server 122, from information read by the processor 102 from a flash drive, or any combination thereof.

In some examples, the priorities module 502 infers and/or selects priorities for the charge profile. For example, the priorities module 502 infers priorities based at least in part on at least one of the following: a past charge profile for any battery 106 of the system 100, a past inputted priority, a quantity of batteries 106 needed for an operation, a future operation time, or any combination thereof.

In some examples, a selected charge profile for a particular charge cycle is stored in a battery profile associated with a specific battery 106 and/or in a memory of the apparatus 600. For example, a user selects a battery ROI charge profile. The charging apparatus 101 performs a charge cycle based on the battery ROI profile. The batteries 106 are deployed in an operation. The battery profile of each battery 106 is updated to indicate that the battery ROI profile was used for a charge cycle. The batteries 106 are returned to the charging apparatus 101 after operation. The system 100 identifies the batteries 106 (e.g., via communication with a BMS 118, scanning an RFID chip 114, scanning a serial number on each battery 106, etc.), and the priorities module 502 determines that the battery ROI profile was used for a previous charge cycle. The priorities module 502 infers a battery ROI priority based on the previous charge cycle, and the profile module 504 either selects the battery ROI profile or constructs a custom battery charge profile based at least in part on a battery ROI priority.

In another example, the priorities module 502 receives user input indicating that the user prioritizes maximizing ROI of the batteries 106 over, for example, rapid charge of the battery 106. However, the user input does not include an explicit selection of a battery charge profile. For an initial charge cycle, the profile selection module 610 selects the battery ROI profile based at least in part on the user input. When the batteries 106 are received by the charging apparatus 101 for a subsequent charge cycle, the priorities module 502 infers a battery ROI priority based at least in part on the previous user input.

In some examples, the apparatus 600 receives input from a user indicating that a given quantity (e.g., 18) of batteries 106 will be needed for a future operation. The apparatus 600 also receives input that the operation will be occurring on a given date and time, such as May 1^{st} at 12:00:00 p.m. In some examples, the priorities module 502 assumes that completing a sufficient charge cycle for the quantity of batteries on or before the given date and time is a priority over other considerations. Accordingly, the priorities module 502 infers a priority of battery availability over long-term SoH, for example. The profile module 504 selects and/or constructs a battery availability profile, which includes a faster charging rate than the long-term SoH charge profile in order to ensure that each battery 106 is sufficiently charged by May 1^{st} at 12:00:00 p.m.

In some examples, the priorities module 502 is configured to assign a battery availability priority to individual batteries based at least in part on the total quantity of batteries 106 currently within the charging apparatus 101. For example, if 18 batteries 106 are needed for an upcoming operation and the charging apparatus 101 is currently only housing 18 batteries 106 or less, the priorities module 502 assigns a battery availability priority to each of the batteries 106.

In some examples, the profile generation module 608 is configured to construct a charge profile based on multiple prioritizes. For example, a battery 106 is needed for an operation at a particular time of 5:00:00 a.m. the following morning. However, the system 100 has also received instructions to charge batteries 106 in a manner that is cost-efficient, secondary to charging the batteries 106 in time for operation. As such, the local processor 102 constructs a custom profile having charge parameters that prioritize battery 106 availability by 5:00:00 a.m. first and cost-efficiency of the system 100 second. For example, the local processor 102 determines that a particular time of day is optimal for cost-efficiency in charging. For example, that time is 1:00:00 a.m. to 3:00:00 a.m. If the current time is 5:00:00 p.m., the cost-efficiency charging schedule has a narrower range than the battery availability schedule. As such, the processor 102 determines that the charge cycle of the battery 106 can be limited to the cost-efficiency hours while complying with the primary priority of sufficiently charging the battery 106 for operation by 5:00:00 a.m. As such, the processor 102 constructs a custom battery charge profile that includes a schedule of battery charging as a charge parameter. In this example, the schedule is 1:00:00 a.m. to 3:00:00 a.m. The custom battery charge profile includes a charge rate sufficient to charge the battery 106 in two hours or less. In some examples, a tertiary priority is maintaining SoH of the battery 106. In such examples, the processor 102 would construct the custom profile to include a charge rate that would optimize the long-term SoH of the battery 106 while constricting the charge cycle to the proscribed schedule and ensuring that the battery 106 is sufficiently charged before the expected operation time.

In some examples, the profile generation module 608 is configured to generate a custom battery charge profile at least in part on two or more priorities and/or two or more battery charge profiles without ranking one priority over the other. For example, some battery charge profiles include charging parameters with both wide and narrow ranges. A first battery charge profile includes a narrow range for charging parameter A, for example, and a wider range for charging parameter B. A second battery charge profile includes a wider range for charging parameter A, and the wider range overlaps and/or includes the narrow range. The second battery charge profile includes a narrower range for charging parameter B, and the range is within and/or overlaps the wider range of the first battery charge profile. In such examples, the processor 102 generates the custom battery charge profile by selecting the overlapping and/or coinciding portions of the ranges for parameters A and B.

The local processor 102 is configured to determine a SoH of each of a number of additional batteries. For example, the local processor 102 determines a SoH of a battery 106a and of each of a number of additional batteries 106b, . . . , 106n. Although FIG. 4 shows each of the number of additional batteries 106b, . . . , 106n within the device 424, examples of the present disclosure are not so limited. In some examples, the local processor 102 also considers batteries not yet used to power the device 424 in determining optimal grouping. For example, the device 424 is powered by eighteen batteries 106. However, the quantity of batteries in the pool of batteries considered for grouping is greater than eighteen.

For example, the device 424 is powered by eighteen batteries 106 for each flight. The local processor 102 determines which of seventy-two batteries 106 to use for an upcoming flight. For example, the local processor 102 determines which batteries 106 to use based on at least one of: battery requirements for the upcoming flight received from a remote server 122 and/or from the device 424; a most recent SoH for each battery 106; a most recent SoC for each battery 106; or a combination thereof. The system 100 then presents the user with the optimal combination of batteries 106. For example, the system 100 presents the serial numbers and/or indicators of the slots 104 of each battery 106 of a combination of batteries 106 determined to be the best combination for the flight.

The apparatus 600 includes a battery grouping module 622. The battery grouping module 622 is configured to select batteries 106 to be grouped together. In some examples, battery grouping module 622 is configured to select batteries 106 to be grouped together based at least in part on the SoH of the individual batteries 106. Examples of the present disclosure include grouping batteries 106 together for use in a device external to the charging apparatus. For example, as shown in FIG. 4, in some examples, the device 424 is powered by multiple batteries 106, and each of these batteries 106 form a group. Grouping batteries 106 with other batteries of similar SoH levels can help to optimize performance and life expectancy of the battery 106. As used herein, the term “grouping” refers to designating two or more batteries 106 as members of a battery group.

In some examples, the discharge profile module 614 and/or the profile module 504 are configured to select and/or generate group charge profiles. In some examples, the group charge/discharge profiles consist of the same parameters described herein in connection with the individual charge/discharge profiles. In some examples, batteries 106 that are part of a group assigned to a group charge/discharge profile are charged/discharged using the same parameters as other batteries 106 in the group. In other examples, batteries 106 that are grouped together for an operation may be charged using different parameters, based at least in part on differences between the batteries 106.

In some examples, the apparatus 600 includes a profile override module 626. The profile override module 626 is configured to determine whether to override an individual battery charge profile with a group battery charge profile, or vice versa. For example, the profile selection module 610 selects a battery charge profile for a battery 106 that is inconsistent with a group battery charge profile for a group that the battery grouping module 622 has assigned the battery to. In some examples, the profile override module 626 determines to override the individual battery charge profile with a group battery charge profile. In some examples, the override is based at least in part on: user input, a ranking of priorities, previous overrides, and/or any combination thereof. In some examples, the profile override module 626 is configured to implement the override during a charge cycle.

In some examples, battery grouping module 622 is configured to perform a battery grouping assessment at a frequency requested by a user. For example, the battery grouping module 622 updates groupings on a weekly basis based on requests from a user. In some examples, the batteries 106 are grouped based on regularly updated SoH measurements. For example, three batteries 106 are grouped together for a first flight based on similar SoH measurements amongst the three batteries 106. However, after the first flight, further SoH measurements of the three batteries 106 and additional batteries 106 indicate that at least one of the three batteries 106 should be grouped with another group of batteries 106 that are now more similar in SoH levels. In such examples, the battery 106 groupings are updated based on subsequent SoH measurements.

In some examples, the battery grouping module 622 is configured to transmit the selection to a user. For example, the battery grouping module 622 transmits an identification of the selected battery 106a to a display 110. In other examples, the battery grouping module 622 transmits the selection to the user via a mobile application of a mobile device connected to the network 120. The selection includes identifying information for the battery 106, such as a serial number.

In some examples, charge cycle module 506 of the battery 106 based on battery groupings. For example, the profile module 504 is configured to determine based at least in part on the SoH of the battery 106 and the SoH of another battery 106 that the battery 106 is grouped with, a goal charge rate of the battery 106. In such examples, the charge cycle module 506 communicates with the communications board 103 to adjust the charging rate of the battery 106. The communications board 103 communicates with the charger board 105 to adjust the charging rate of the battery 106. In some examples, the charger board 105 is also configured to adjust the charging rate of the battery 106 without communication from the communications board 103 in the event that connection between the charger board 105 and the communications board is lost. In some examples, the charger board 105 has a pre-set safety limit. The charger board 105 is configured not to allow a charging rate greater than the pre-set safety limit, even if the communications board 103 instructs the charger board 105 to charge at such a rate.

In some examples, the switch 124 includes a relay. In some examples, the communications board 103 is a control circuit, and the battery 106 and power supply 107 are connected as part of a controlled circuit. In some examples, the switch 124 provides isolation between the communications board 103 and the controlled circuit. In some examples, the switch 124 includes an electromechanical relay. In other examples, the switch 124 includes a solid-state relay. In some examples, the switch 124 includes a board with multiple switches configured to control flow of current to different batteries 106 and/or battery cells. In some examples, the switch 124 is part of the charger board 105, shown in FIG. 2.

In some examples, adjusting the charging rate of the battery 106 is done on a battery cell 112 basis. For example, the charger board 105 and/or the switch 124 includes a switch corresponding to each cell 112a, 112b of the battery 106 and directs current flow to a first battery cell 112a at a different rate than to a second battery cell 112b.

In some examples, the charge profiles include a long-term battery SoH profile. The long-term battery SoH profile includes charging parameters that are configured to optimize battery SoH. Charging parameters of the long-term battery SoH profile include, for example, maximum SoC, length of time of charge cycle, charging rate, ambient temperature, battery 106 temperature, length of time that the battery 106 is connected to the charging apparatus 101, and/or any combination thereof.

In some examples, the long-term battery SoH profile includes a slower charging rate than other charge profiles. For example, the charging rate is not greater than 1% of the battery 106's capacity per minute. For example, the long-term SoH profile for a battery 106 with a capacity of 1000 Ah includes a charging rate of not greater than 10 Ah per minute. In some examples, the charging rate per minute is not less than 0.5% of the battery 106 capacity.

In some examples, the long-term battery SoH profile includes a lower maximum SoC than other charge profiles. In some examples, SoH for the battery 106 is optimized by a maximum SoC of less than 100%, such as 80%. For example, the long-term battery SoH charge profile includes a maximum SoC of not less than 75% and not more than 85% of the battery's 106 actual maximum SoC.

In some examples, the long-term battery SoH profile includes an ambient temperature range. The “ambient temperature” refers to the ambient temperature of the slot 104. Although not shown in the figures, in some examples, the system 100 includes one or more temperature sensors to measure ambient temperature within slots 104 of the apparatus 101. In some examples, the system 100 is configured to adjust the ambient temperature of the slots 104 via one or more cooling elements, such as fans, pumps, and/or hoses. For example, although not pictured, the apparatus 600 includes a temperature adjustment module configured to determine to decrease or increase the ambient temperature of a slot 104 and instruct a component of the system 100 to supply more power or less power, respectively, to the cooling elements of and/or proximate to that slot 104.

In some examples, the long-term battery 106 SoH profile includes an ambient temperature charging parameter of not less than 10 and not greater than 30° C. For example, the temperature charging parameter is approximately 15° C. The temperature charging parameter is based at least in part on the type of battery 106.

In some examples, the long-term battery SoH profile includes a battery temperature charging parameter. Unlike the ambient temperature parameter, the battery temperature parameter refers to the actual temperature of the battery 106 rather than the ambient temperature of its slot 104 (although one of skill in the art will appreciate that the ambient temperature of the battery 106's environment will affect the temperature of the battery 106). In some examples, the charger board 105 is configured to read the battery 106 temperature during the charge cycle and transmit this data to the communications board 103 and/or to local processor 102. In other examples, the BMS 118a of the battery 106a is configured to measure and transmit battery 106 temperature. Additionally or alternatively, the system 100 includes a thermal camera having the battery 106 within its field of view (e.g., a thermal camera mounted in a slot 104) and/or an infrared thermometer to read the battery 106 temperature. In some examples, the long-term battery SoH profile includes a battery temperature of not less than 0 and not greater than 45° C.

In some examples, a charging parameter of the long-term battery SoH profile includes a length of time for the battery 106 to be connected to the charging apparatus 101. For example, a component of the charging apparatus 101 (e.g., a sensor) and/or a BMS 118 of a battery 106 is configured to determine that a battery 106 has been electrically connected to the charging apparatus 101 a threshold period of time after the end of the charge cycle. In some examples, the threshold period is relatively short (e.g., one minute). The apparatus 600 transmits a notification to a user based on the determination. For example, the processor 102 transmits a notification to the user through a display 110 and/or to a remote computing device. The notification indicates that a battery has been left connected to the charging apparatus 101 after the charge cycle and/or advises the user to disconnect the battery 106 to preserve its long-term health. In some examples, the notification includes an identification number for the battery 106 and/or for the slot 104 that the battery 106 is located in. In some examples, the system 100 transmits the notification based on determining that a battery 106 has been connected to the charging apparatus 101 for a total time that is greater than a threshold total time.

Although not shown in FIG. 6, in some examples, the apparatus 600 includes a machine learning module. The machine learning module is configured to determine charging and/or discharging parameters for a battery 106 based at least in part on learned outcomes based on input charging conditions for that battery 106 and/or for a similar battery. Outcomes include, for example, a SoH and/or SoH rate of degradation for that battery 106. Inputs include, for example, any of the charging parameters and/or discharge parameters described herein. Although not shown in FIG. 6, in some examples, the apparatus 600 includes a SoH model module configured to use machine learning techniques to determine relationships between battery SoH and charging parameters. In some examples, the profile generation module 608 is configured to determine and/or adjust at least one of a charging parameter of a charge profile. In some examples, the discharge profile generation module 616 is also configured to adjust/and or generate a discharge parameter of a discharge profile based at least in part on past and/or simulated outcomes.

In some examples, the profile generation module 608 is configured to infer the charging parameters based at least in part on past charging parameters and past SoH measurements for a particular battery 106 and/or for other batteries 106 of the system 100. In some examples, the profile generation module 608 determines optimal charging parameters for long-term battery SoH based on these past measurements and inputs. For example, the profile generation module 608 uses a machine learning algorithm that is trained on a corpus of data that includes, for example: characteristics of batteries charged by the charging apparatus 101 in the past, charging parameters of previous charging cycles, SoH measurements of batteries 106, changes in SoH measurements of batteries 106 (e.g., before and after charge cycles), and/or any combination thereof. The machine learning algorithm uses characteristics of the battery 106 being charged and/or fixed charging parameters as input and outputs charging parameters for optimal SoH. The profile generation module 608 constructs the long-term battery 106 SoH profile based at least in part on this output.

In some examples, the apparatus 600 includes a battery grouping module 622 configured to assign batteries 106 to groups. In some examples, the batteries 106 in each group are charged according to the same charge profile. In some examples, the long-term battery SoH profile for a particular battery 106 is based at least in part on a battery grouping, or an identification of batteries 106 to be employed together during an operation. For example, a charging parameter of this profile includes maximum state of charge (“SoC”) to which the battery 106 should be charged before the charge cycle ends. In some examples, the SoC is based at least in part on the SoH of the battery 106 and the SoH of other batteries 106 that the battery 106 is grouped with.

For example, two 5V batteries 106 are grouped together. However, due to declining SoH, one of the batteries 106 can only be charged to a maximum SoC of 4.8V. In some examples, the communications board 103 determines the maximum possible SoC for a battery 106 and transmits that maximum to the local processor 102. In some examples, the second battery 106 is still capable of being charged to 5V. However, to preserve SoH of both batteries 106, the long-term battery SoH charge profile for the second battery 106 includes maximum SoC charging parameter of 4.8V, matching the actual maximum SoC of the first battery 106.

In some examples, a maximum SoC charging parameter is expressed as a percentage. For example, the local processor 102 determines, based on a SoH of the battery 106 and the SoH of other batteries 106 that the battery 106 is grouped with, that the ideal SoC that the battery 106 to be charged to is 80% charge rather than 100% charge and updates the long-term SoH battery charge profile accordingly.

In some examples, the charge profiles include a battery performance profile. The battery performance profile includes charging parameters for optimal battery performance over a given number of charge cycles. For example, the apparatus 600 receives input instructing the system 100 to optimize battery performance over three charge cycles. In such examples, the profile generation module 608 constructs the battery performance profile based on charging parameters to optimize battery performance in the periods following three charge cycles. In some examples, the charging parameters of the battery performance profile are different than, for example, the charging parameters of the long-term battery SoH profile.

In some examples, the battery performance profile is based at least in part on data relating to the battery 106. For example, the data includes parameters of past charging cycles. In some examples, the parameters are part of a record of past charging parameters for the battery 106. This record is stored, for example, in a BMS 118 of the battery 106, in memory in communication with the local processor 102, in an RFID chip 114 of a battery, on a cloud network (e.g., network 120), and/or on the remote server 122.

In some examples, the data relating to the battery 106 includes a record of past performance of the battery. This “performance” takes place, for example, while battery 106 powers a device, while the battery 106 is fully charged but not in use, while the battery is being charged and/or discharged by the apparatus 101, and/or any combination thereof. For example, the record indicates how well the battery performed during a particular operation. Performance parameters include, but are not limited to, a rate of discharge during an operation, a self-discharge rate of the battery 106, and operating temperature range, a rate of physical expansion (e.g., swell) of the battery 106 during past charging cycles, impedance measurements for the battery 106, and/or any combination thereof. In some examples, each of the performance parameters is assigned to a previous charge cycle.

As will be discussed herein, in some examples, the system 100 is configured to discharge the battery 106 and to take measurements on the battery 106 before, during, and after discharge. In some examples, the performance parameters are based on those measurements. In some examples, the system 100 discharges the battery 106 in a discharge cycle that is configured to simulate regular operation of the battery 106. As such, examples of the present disclosure allow the user to select charging parameters for the battery 106, simulate operation of the battery 106 with those parameters via discharge without removing the battery 106 from the slot 104, and determine the performance effects of those charging parameters.

Although not shown in the Figures, in some examples, the system 100 includes an apparatus (e.g., apparatus 500, 600, and/or remote server 122) that includes a battery performance model module. The battery performance model module is configured to train the model using the battery charge parameters as inputs and the subsequent battery performance parameters as outputs. In some examples, the battery performance model module is configured to use the model to determine charging parameters for optimal performance and generate the battery performance profile based on those charging parameters.

In some examples, the profile generation module 608 is configured to generate the battery performance profile based at least in part on information inferred about the battery 106. For example, a component of the system 100 reads data from the battery 106 and determines the battery's type. In some examples, the system 100 determines that a first battery 106 has one or more characteristics that are similar to a second battery 106 that has been charged and/or discharged by the charging apparatus 101. Such characteristics include, for example, overall SoH, age, battery type (e.g., lithium ion), and a characteristic of the device that the battery 106 is configured to power (e.g., UAV, all-electric vehicle (AEV), etc.). Based on this determination, the profile generation module 608 generates a battery performance charge profile for that first battery 106 based at least in part on measurements, charging parameters, simulations, etc., for the second battery 106.

In some examples, the charge profiles include a battery availability profile. For example, the battery availability profile includes a time and/or date of a future operation of the battery 106 and/or a time and/or date that the battery 106 will need to be finished charging in order to be available for a future operation. Parameters of the battery availability profile include, for example, charge rate(s), charge cycle start time, charge cycle end time, charge cycle length, battery temperature, final SoC, and/or any combination thereof.

For example, the profile module 504 determines a battery charge rate based at least in part on the future time and/or date that the charging will need to be complete in order for the battery 106 to be available for operation. The profile module 504 also determines a range of charge cycle start times, which indicate a range of times that the charge cycle can be initiated while ensuring that the battery 106 has a charge sufficient for operation (i.e., final SoC) by the end of the charge cycle. In some examples, the charge cycle start time range is determined based at least in part on: battery type, operation date/time, power capable of being safely fed to the battery 106 by its power supply 107, a minimum SoC needed for operation (e.g., final SoC), and/or any combination thereof.

In some examples, the battery availability profile includes one or more charge rates that are a function of the start time of the charge cycle. For example, a charge cycle that ends at 13:00:00 will need faster charging rates if it starts at 12:00:00 than if it starts at 8:00:00.

In some examples, the battery availability profile also includes a battery temperature parameter. In some examples, increasing the temperature of the battery 106 helps the battery 106 to charge at faster rates. As such, in some examples, the battery availability profile includes a range of battery temperatures. In some examples, the highest boundary of this range is higher than the highest boundary of the battery temperature range for the long-term SoH profile.

The battery availability profile includes parameters that are interdependent. For example, the charging rate of the battery 106 depends at least in part on a begin time of the charge cycle. In some examples, a fixed subset of the charging parameters are based at least in part on at least one of the following: user input, inferences, other priorities and/or charge profiles, system 100 settings, and/or any combination thereof. In such examples, a dynamic subset of charging parameters is based at least in part on the fixed subset of charging parameters.

In some examples, the charge profiles include a battery return on investment (“ROI”) profile. The battery ROI profile includes charging parameters determined in order to maximize the user's return on investment for an individual battery 106. As used herein, “battery ROI” refers to a comparison (e.g., difference, percentage, ratio, etc.) of the net gain resulting from the battery 106 and the total costs, both monetary and otherwise, of charging and/or using the battery 106.

In some examples, the battery ROI profile includes charging parameters selected based on activity of the battery 106 over a given time period. For example, the local processor 102 constructs the battery ROI profile to maximize ROI for that battery 106 over a 3-month period. In Such an example, the battery ROI profile includes charging parameters that are selected based at least in part on the activity of that battery 106 over the 3-month period.

In some examples, the profile generation module 608 constructs the battery ROI profile by determining the overall costs of charging and/or operating the battery 106 in a given time period as a function of charging parameters. The costs of charging include, for example, SoH degradation of the battery 106, SoH degradation of another battery grouped with battery 106 due to the SoH of the battery 106, loss of profits from an operation due to sub-optimal performance of the battery 106, costs for battery repair and replacement, investments required for charging, cost per battery 106 per charge cycle, rental costs per battery 106 over a given period, and/or any combination thereof.

In some examples, the profile generation module 608 constructs the battery ROI profile based at least in part on overall benefit from charging/operating the battery, as a function of charging parameters. The benefits include, for example, a portion of profit generated by an operation involving the battery 106 (e.g., profit from a UAV delivery of retail items, where the UAV is powered at least in part by the battery 106). In some examples, overall benefit of a battery 106 is a custom designation. For example, the processor 102 is configured to receive input from the user regarding an outcome type to use for the net benefit analysis. Such outcomes include, for example, successful completion of missions (determined, for example, based at least in part on user input and/or information from the device 424 the battery 106 powers).

In some examples, the profile generation module 608 constructs the battery ROI profile via mathematical simulation. For example, the profile generation module 608 uses a mathematical model with charging parameters as inputs. In some examples, the mathematical model includes at least one of the following outputs: battery performance, monetary cost of a charge cycle, net profits resulting from operation of the battery 106, battery SoH, SoH of another battery grouped with the battery, and/or any combination thereof. As discussed above, in some examples, the mathematical model is trained on a corpus of data that includes actual measurements from the battery 106 and/or other batteries 106 with at least one similar characteristic. In some examples, the corpus also includes data from discharge cycles that simulate operation of the battery 106 and/or of other batteries 106 with at least one similar characteristic.

In some examples, the charge profiles include system ROI profile. The system ROI profile includes charging parameters determined in order to maximize the user's return on investment for an overall system 100 rather than just an individual battery 106. As used herein, “system ROI” refers to a comparison (e.g., difference, percentage, ratio, etc.) of the net gain resulting from the system 100 and the total costs, both monetary and otherwise, of operating the system 100 to charge a number of batteries 106.

In some examples, the system ROI profile includes charging parameters selected based on activity of a number of batteries 106 over a given time period. For example, the profile generation module 608 constructs the battery ROI profile to maximize ROI for a system 100 over a 3-month period determined, for example, based at least in part on user input. In such an example, the system ROI profile includes charging parameters that are selected based at least in part on the activity of the batteries 106 and/or other components of the system 100 over the 3-month period.

In some examples, the profile generation module 608 constructs the system ROI profile by determining the overall costs of charging and/or operating the system 100 (including batteries 106) in a given time period as a function of charging parameters. The costs of charging include, for example, any of the costs of charging described in connection with the battery ROI profile. However, the costs of charging additionally include, for example, maintenance costs, degradation, and/or replacement of other components of the system 100, such as components of the charging apparatus 101. For the system ROI profile, the costs of charging also include, in some examples, rental costs for the system 100, costs of using the power source 108, other utility costs for the system 100, and/or any combination thereof.

In some examples, the profile generation module 608 constructs the system ROI profile based at least in part on overall benefit from charging/operating the batteries 106, as a function of charging parameters. The benefits include, for example, any of the benefits described in connection with the battery ROI profile.

In some examples, the profile generation module 608 constructs the system ROI profile via mathematical simulation. For example, profile generation module 608 uses a mathematical model with charging parameters as inputs. In some examples, the mathematical model includes at least one of the following outputs: battery 106 performance, monetary cost of a charge cycle, net profits resulting from operation of the batteries 106, battery SoH, and/or any combination thereof. As discussed above, in some examples, the mathematical model is trained on a corpus of data that includes actual measurements from the batteries 106 106 and/or other batteries with at least one similar characteristic. In some examples, the corpus also includes data from discharge cycles that simulate operation of the batteries 106 and/or of other batteries with at least one similar characteristic.

In some examples, the profile generation module 608 is further configured to aggregate costs, benefits, and/or ROI for individual batteries 106, and/or for the charging apparatus 101, and the system ROI profile is based at least in part on that aggregation.

In some examples, the charge profiles include a power source compatibility profile. The power source compatibility profile includes charging parameters configured to ensure compatibility with the power source 108. In some examples, the power source compatibility profile includes ranges of charging parameters. These ranges reflect the power source 108's capacity to provide power to the batteries 106 during a charge cycle. For example, a power source 108 includes a solar panel, and a charging parameter includes a charging schedule reflecting a time of day during which the power source 108 will most likely be able to supply maximum power (e.g., 10:00:00-14:00:00, depending on weather conditions).

In some examples, the charge profiles include a system capacity profile. The system capacity profile includes charging parameters based on the overall power output capacity of the system 100. In some examples, the profile module 504 is configured to generate a system capacity profile that maximizes the charging power output of the system 100. For example, the system 100 has a maximum capacity that allows it to charge 24 batteries 106 at a first charging rate consecutively. In some examples, the system 100 determines that an additional battery 106 has been inserted into the charging apparatus 101. In response, the system capacity charge profile is updated to decrease the charging rate to a second charging rate that is lower than the first charging rate.

In some examples, the charge profiles include an environmental impact profile. The environmental impact profile includes, for example, charging parameters selected to reduce the environmental impact of the overall system 100. Environmental impact includes, for example, electricity consumption, emission of carbon and/or other pollutants, level and/or duration of noise (e.g., noise sufficient to disrupt wildlife and/or people), fuel from the power source 108, and/or any combination thereof. Examples of charging parameters varied to reduce environmental impact of the system 100 include, for example, charge cycle start time, charge cycle end time, charging rate, and/or any combination thereof. For example, an environmental impact profile includes a charge cycle schedule of off-peak hours to reduce environmental impacts. In some examples, the environmental impact profile includes relatively fast charging rates.

In some examples, one or more charging parameters of the charge profile varies throughout the charge cycle. For example, the charging profile includes a first rate of charge during the first hour of the charge cycle and a second rate of charge that is different from the first rate of charge during the second hour of the charge cycle. In some examples, the profile module 504 generates and/or selects such a charge profile, the charge cycle module 506 actuates such adjustments throughout the charge cycle through communication with the communications board 103 throughout the cycle. In some examples, the communications board 103 receives the schedule for each charging parameter prior to the charge cycle and automatically adjusts the parameters on time by instructing the charger board 105 and/or power supply 107 accordingly. For example, the communications board 103 the charger board 105 and/or the power supply 107 to charge the battery 106 at the first rate during the first hour of the charge cycle. The communications board 103 determines that an hour or more has passed and automatically instructs the charger board 105 and/or the power supply 107 to adjust the charge rate to the second charge rate, according to the battery charge profile. As such, in some examples, the charging apparatus 101 is configured to dynamically adjust a charging parameter during a charge cycle.

In some examples, some the charge profiles include dynamic charge profiles. For example, the profile module 504 generates and/or selects a static charge profile. The static charge profile includes charging parameters. The static charge profile is applied throughout the charge cycle. In some examples, the static charge profile includes charging parameters that change throughout the charge cycle. For example, a charging rate slows as the charge cycle progresses. However, even those changes are made based on the schedule of charging rates dictated by the static charge profile. On the other hand, in some examples, the profile module 504 generates and/or selects a dynamic charge profile. A dynamic charge profile includes charging parameters and/or protocols that are updated mid-cycle. For example, the dynamic charge profile includes a charging rate that is updated mid-cycle based on, for example, measurements from the battery 106, input from a user, and/or any combination thereof. In such examples, the profile generation module 608 is configured to adjust charging parameters mid-cycle. In some examples, the profile selection module 610 is configured to select a static profile and to subsequently change the selection from the static profile to a dynamic profile during the charge cycle. For example, the profile selection module 610 updates the profile selection from the static profile to the dynamic profile automatically in response to receiving input, such as a revised charging schedule and/or an updated charging priority. In such examples, the parameters of the dynamic profile are implemented during the charge cycle.

For example, the apparatus 600 receives data indicating that the battery 106 is at a 95% charge with over an hour remaining before the expected future operation time. In response, the local profile generation module 608 slows a charging rate parameter of a battery availability profile to maintain long-term battery SoH while ensuring that the battery 106 will be ready in time.

In some examples, the priorities module 502 is configured to update a charging priority mid-cycle based at least in part on data read from the battery 106 mid-cycle. In some examples, the profile module 504 is configured to select, de-select, generate, and/or re-generate a charge profile based at least in part on the updated charging priority.

In some examples, the system 100 collects charge battery data during the charge cycle. For example, a BMS 118a of an intelligent battery 106a transmits the charge battery data to the communications board 103a. In some examples, the charger board 105 is configured to read the charge battery data and transmits it to the communications board 103. For example, the charger board 105b reads charge battery data from an unintelligent battery 106b that does not have a BMS 118.

In some examples, the charge cycle module 506 is configured to terminate a charge cycle based on a determination that a charging parameter of the charge profile has been met. Such charge parameters include, for example, charge cycle length, maximum SoC, and or total charge cycle length. For example, during a charge cycle, the communications board 103 determines a SoC of a battery 106 based on readings from the charger board 105. The communications board 103 transmits the SoC to the local processor 102. In another example, the local processor 102 determines the SoC based on communication with a BMS 118 of the battery. The charge cycle module 506 determines that the SoC is greater than or equal to 80% and terminates the charge cycle. For example, the local charge cycle module 506 terminates the charge cycle through communication with the power supply 108 and/or with a switch controlling charge current to the battery 106.

Although the apparatus 101 is referred to herein as a “charging apparatus 101,” functions of the apparatus 101 are not limited to charging the batteries 106. As described herein, functions of the charging apparatus 101 also include, for example, discharging the batteries 106. In addition to and/or in alternative to running a charge cycle, in some examples, the apparatus 101 is configured to run a discharge cycle (directing current out of the battery 106 to lower the SoC of the battery 106). In some examples, the battery 106 remains in the same slot 104 for both the charge and discharge cycles.

The term “discharge cycle” refers to a period of time during which a battery is discharged to any degree. In some examples, the battery 106 is completely discharged during the “discharge cycle.” In other examples, the battery is discharged to a SoC level determined by at least one of a user input and a battery discharge profile. For example, the SoC level is a level simulating the total decrease in SoC over a potential future operation of the battery 106.

As used herein, the terms “full charge cycle” and “full discharge cycle” may refer to periods of time during which the battery is fully charged or fully discharged, respectively. In some examples, the system 100 determines a SoC that constitutes a full SoC for that battery. For example, a battery has a full SoC of 100%. In another example, another battery that is grouped with a battery having a lower capacity is considered “fully charged” at a SoC of 90%.

In some examples, the charging apparatus 101 discharges the battery 106 based at least in part on a discharge profile. As used herein, “discharge profile” refers to one or more parameters for charging battery 106 and/or a set of instructions to the apparatus 101 for discharging the battery 106.

The apparatus 600 includes a discharge profile module 614. In some examples, a multitude of discharge profiles are stored in a memory (e.g., a memory of the apparatus 600), and the discharge profile module 614 includes a discharge profile selection module 618 configured to select a discharge profile from the multitude of discharge profiles. The selected discharge profile has pre-determined discharge parameters. In some examples, the discharge profile module 614 includes a discharge profile generation module 616 configured to generate discharge parameter values that make up a generated discharge profile. In some examples, the discharge profile module 614 determines a discharge profile for an individual battery 106. In other examples, the discharge profile module 614 determines a discharge profile for a group of batteries 106 selected by the battery grouping module 622, and the discharge parameters are applied to each of the batteries 106 during the discharge cycle.

The apparatus 600 includes a discharge cycle module 624 configured to communicate the discharge parameters of the discharge profile to the communications board 103 during and/or before the discharge cycle. In some examples, the discharge profile dictates discharge parameters for a particular discharge cycle. In some examples, the discharge profile also dictates the timing and frequency for discharge cycles.

Examples of discharge parameters include, but are not limited to: a rate of discharge, a discharge schedule (e.g., a start time/date and/or a stop time/date of the discharge cycle), a final level of charge (SoC) at the end of the discharge cycle, length of time of the discharge cycle, ambient temperature of the battery's 106 environment during the discharge cycle, a frequency of current adjustment within the discharge cycle, or any combination thereof.

The discharge profile module 614 selects a discharge profile from one or more discharge profiles and/or builds a discharge profile based on a battery discharge preference, priority, and/or simulation condition. For example, discharging a battery 106 at a fast rate will make the battery 106 available for re-charge at an earlier time, but a slower charging rate may more accurately simulate use of the battery 106 while powering a device (e.g., device 424). As such, the system 100 determines whether to prioritize simulation or battery availability and selects a discharge profile accordingly.

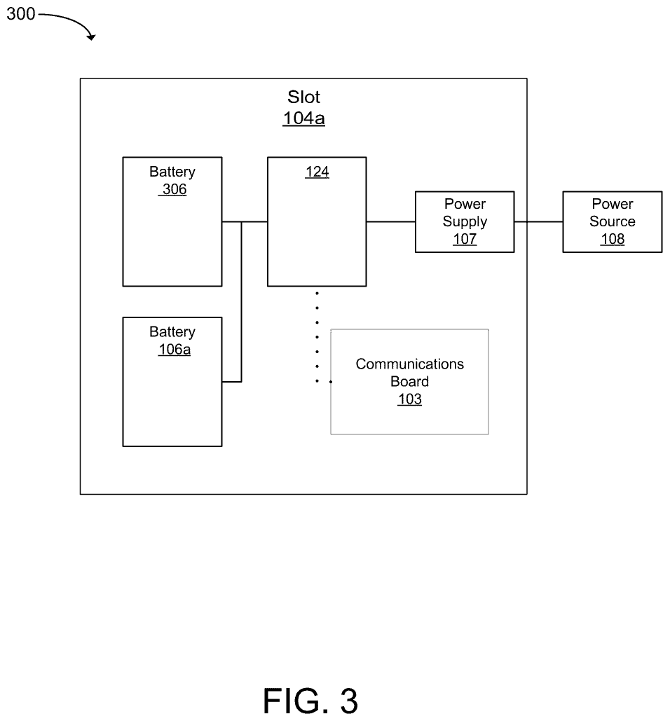

Priorities include, but are not limited to: simulation of operational conditions, discharge for storage, long-term battery SoH, battery performance, battery availability, battery 106 return on investment (“ROI”), system 100 ROI, power source compatibility, environmental impact, system 100 power, mission success (e.g., meeting mission-specific goals during operation) or any combination thereof. As shown in FIG. 3, in some examples, the charging apparatus 101 is configured to discharge a first battery 106a into a load battery 306. As such, discharge priorities of the battery 106a include, in some examples, charging priorities of the load battery 306.

In some examples, priorities module 502 and/or an operational metric module 620 are configured to determine the battery discharge preference and/or priority based at least in part on: user input, inferred user preferences, a quantity of the batteries 106, a future operation time, type of load the battery 106 is being discharged into, and/or a combination thereof. In some examples, the discharge profile module 614 selects and/or determines the battery discharge profile in any suitable manner, such as those described above in connection with selection of the charge profile. As discussed above in connection with charge profiles, in some examples, the discharge profile generation module 616 is configured to generate the battery discharge profile based at least in part on multiple discharge priorities.

Discharge profiles include, for example, simulation discharge profiles. A simulation discharge profile includes a number of discharge parameters designed to simulate operational conditions of the battery 106 after charging (e.g., operation of the battery 106 while powering the device 424). When a simulation discharge profile is selected, the operational metric module 620 conditions for the discharge cycle that resemble operational conditions of use (or “operational metrics”) of the device 424.

For example, the operational metric module 620 receives operational metrics from the device 424. The operational metrics include data collected from the battery 106 while the battery 106 powers the device 424. For example, the operational metrics include at least one of the following for a particular battery 106: total time of discharge in the device 424, SoC over time, initial SoC, final SoC, ambient temperature, battery temperature, cell voltage, battery voltage, input current, output current, and/or any combination thereof. In some examples, a user inputs the operational metrics to the local processor 102 via a GUI and/or input devices connected to the display 110. In some examples, a discharge metric varies over the length of the discharge cycle to mimic variation in operational metrics throughout use.

In some examples, the operational metric module 620 receives the discharge metric from at least one of a remote server 122, remote computing device, or input via a GUI of the display 110. For example, a user inputs the preferred discharge metric and/or selects a battery care profile including the preferred discharge metric via a dashboard of a web application on a remote computing device.

For example, the local processor 102 is a processor of a computing device that receives a flash drive with the operational metrics stored thereon. In other examples, the device 424 transmits the operational metrics to at least one of an RFID chip 114 and/or a BMS 118 of the battery 106. The communications board 103 then reads the operational metrics from the BMS 118 and/or the RFID scanner 116. In other examples, the display 110 includes a graphical user interface through which the user inputs the operational metrics. In another example, the remote server 122 receives the operational metrics. In some examples, the operational metric module 620 is configured to receive the operational metrics from a mobile application and/or a web application of a remote computing device. For example, the operational metric module 620 is configured to receive the operational metrics over a network connection or other wireless connection, such as Bluetooth®.

In some examples, the operational metrics include a battery discharge rate. For example, the operational metrics include a rate at which the battery 106 was discharged during a use of the device 424 and/or will likely be discharged during future use of the device 424. In some examples, the battery discharge rate varies over the discharge cycle.

In some examples, the communications board 103 and/or the charger board 105 causes the battery 106 to discharge at a rate that is within an acceptable deviation of the operational discharge rate. For example, the charger board 105 receives operational metrics, such as the operational discharge rate and acceptable deviation, from the communications board 103. The charger board 105 reads discharge battery data, such as a SoC from the battery 106, and transmits the discharge battery data to the communications board 103. The communications board 103 transmits the discharge battery data, such as the SoC, to the local processor 102. In other examples, the communications board 103 reads the discharge battery data directly.

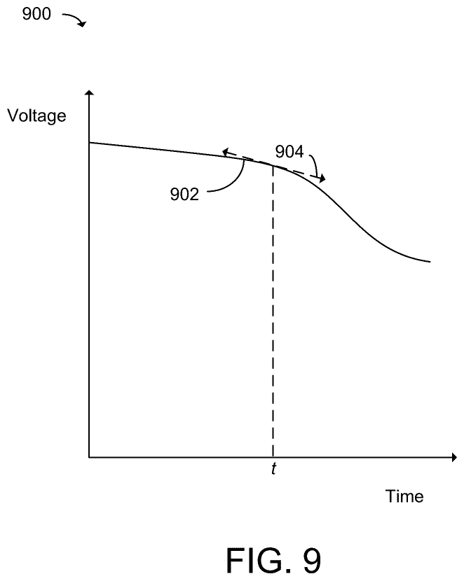

An “operational discharge rate” includes a rate at which the battery 106 has been discharged or is likely to be discharged during use in the device 424. In some examples, the operational discharge rates are non-linear. For example, FIG. 9 shows a graph 900 of voltage of a battery 106 over time while the battery 106 is in use in the device 424. As shown in FIG. 9, the relationship is represented by the function 902, which is a non-linear function. As such, the operational discharge rate changes over time. In some examples, the local processor 102 receives the function 902 from the device 424, determines discharge rates for each time t along the function 902, and transmits those discharge rates to the communications board 103. At a time t of the discharge cycle, the communications board 103 instructs the charger board 105 to discharge the battery 106 at a rate equivalent to the operational discharge rate, defined by the slope of the tangential line 904 at time t of the operational period. In some examples, the function 902 is part of a discharging profile for a battery 106, and the discharging profile includes discharging parameters determined and/or selected to mimic the discharge function 902 in the battery 106 in a discharge cycle.

In some examples, the operational metric module 620 is configured to compare the discharge battery data to at least one of the operational metrics. In some examples, the operational metric module 620 is configured to perform a calculation to compare the discharge battery data to the operational metrics. For example, the local processor 102 receives the SoC and determines a discharge rate based at least in part on the SoC.

In some examples, the operational metric module 620 is configured to determine a discharge battery metric based on the discharge battery data. The operational metric module 620 then compares the discharge battery metric to a corresponding operational metric. For example, the operational metric is a temperature of the battery 106 during flight. The operational metric module 620 determines a discharge temperature of the battery based on the battery discharge data and compares the discharge temperature to the operational temperature.

The operational metric module 620 determines whether the discharge metric is within a threshold of the operational metric. If the discharge metric is not within a threshold of the operational metric, the operational metric module 620 instructs the discharge cycle module 624 to adjust, based on the comparison to the operational metric, the discharge metric. For example, the operational metric module 620 determines that the discharge rate of the battery 106 is outside of a threshold deviation from a discharge rate of the battery 106 during a flight. In response, operational metric module 620 instructs the discharge cycle module 624 to adjust a discharge rate of the battery 106. The adjustment is during the discharge cycle.

An “operational discharge rate” includes a rate at which the battery 106 has been discharged or is likely to be discharged during use in the device 424. In some examples, the operational discharge rates are non-linear. For example, FIG. 9 shows a graph 900 of voltage of a battery 106 over time while the battery 106 is in use in the device 424. As shown in FIG. 9, the relationship is a curve 902 and is not linear. As such, the operational discharge rate changes over time. The local processor 102 receives the curve 902 from the device 424, determines discharge rates for each time t along the curve, and transmits those discharge rates to the communications board 103. At a time t of the discharge cycle, the communications board 103 instructs the charger board 105 to discharge the battery 106 at a rate equivalent to the operational discharge rate, defined by the slope of the tangential line 904 at time t of the operational period.

In some examples, the discharge cycle involves discharging the battery 106 to a degree that is within an acceptable deviation of an operational discharge degree. For example, the local processor 102 receives data indicating that a 1000 mAh battery 106 has provided a current of 6000 mA over a period of one hour. The system 100 discharges the battery 106 at a rate sufficient to discharge a similar amount of current during a desired discharge cycle time. For example, the desired discharge cycle time is ten minutes. The charger board 105 discharges the battery 106 at a rate of 6 C. In other words, during the discharge cycle, a battery 106 of 1000 mAh provides 6000 mA of charge for ten minutes. In such examples, the charger board 105 discharges the battery 106 at a rate of 6 C, allowing the discharge cycle to be completed in approximately ten minutes.

In some examples, the operational metric module 620 receives operational data for a future operational cycle. For example, a future operational cycle (e.g., flight) is expected to take place in a given location (e.g., Austin, Texas) on a particular date. The operational metric module 620 receives and/or determines a forecast for that location and that date. For example, the processor 102 predicts a temperature of 90 degrees Fahrenheit on the expected day of operation. During the charge and/or discharge cycle, the communications board 103 adjusts the conditions of the battery 106 and/or of the charging/discharging environment. For example, the slot 104 is a closed chamber, and the chamber includes one or more temperature sensors in communication with the communications board 103. The communications board 103 reads a temperature of the slot 104 from the sensor. If the temperature is outside of an acceptable deviation from the predicted operational temperature, the communications board 103, to bring the temperature within the acceptable deviation, increases or decreases power supplied to cooling elements, such as fans or cooling hoses.

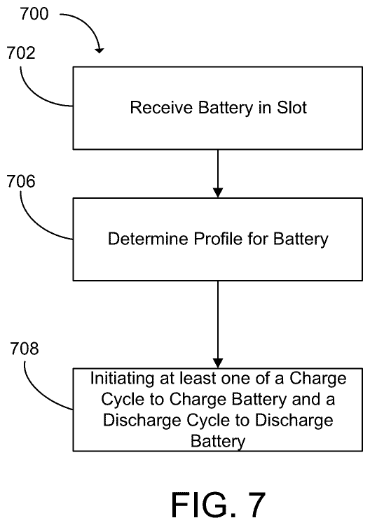

FIG. 7 illustrates one example of a method 700, according to examples of the present disclosure. The method 700 begins and includes receiving 702 a battery 106 in a slot 104. The battery 106 is removable from the slot 104 to power a device (e.g., 424) separate from the slot 104.

In some examples, the method 700 includes determining 706 a profile for the battery 106. The profile includes at least one of a charging parameter based at least in part on a charging priority for the battery, a discharging parameter based at least in part on a discharging priority for the battery, or a combination thereof. The method 700 includes initiating 708 at least one of: a charge cycle to charge the battery based at least in part on the charging parameter while the battery is received by the slot and a discharge cycle to discharge the battery based at least in part on the discharging parameter while the battery is received by the slot.

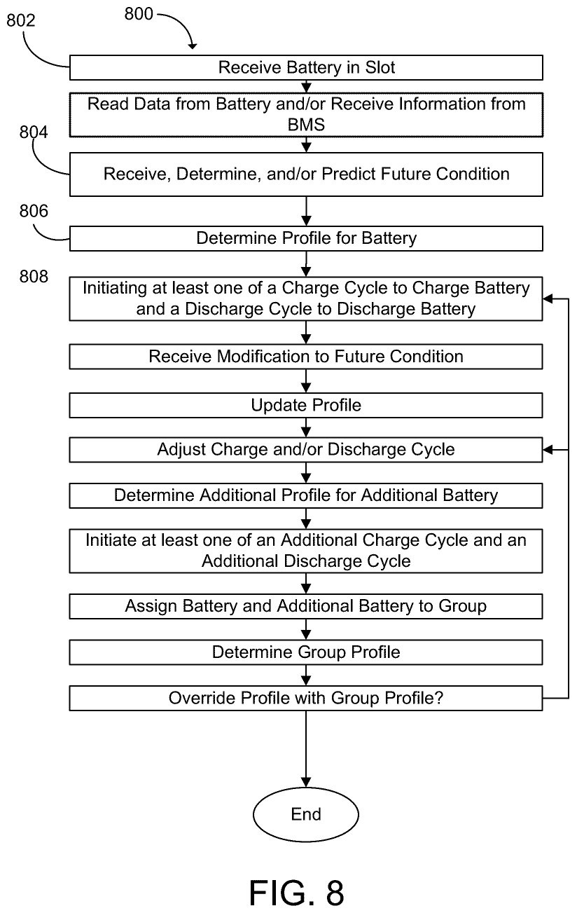

FIG. 8 illustrates one example of a method 800. In some examples, the method 800 is performed by the apparatus 500 and/or 600. In some examples, the method 800 includes receiving 802 a battery 106 in a slot 104. The battery 106 is removable from the slot 104 to power a device (e.g., 424) separate from the slot 104. In some examples, the method 800 includes reading and/or receiving 803 data from the battery 106 and/or a BMS of the battery 106.

The method 800 includes, in some examples, a step 804 of receiving, determining, and/or predicting a future condition for the battery 106. The profile is further based at least in part on the future condition. In some examples, the future condition is a future time of operation for the battery 106, and the method 800 includes receiving 810, during the charge and/or discharge cycle, a modification to the future time of operation. The method includes updating 812 the profile during the charge and/or discharge cycle based at least in part on the modification and adjusting 814 the charge and/or discharge cycle accordingly.

In some examples, the method 800 includes determining 816 an additional profile for an additional battery 106. The additional profile includes an additional charging parameter and/or additional discharging parameter. The method 800 includes initiating 818 at least one of an additional charge cycle and an additional discharge cycle to charge and/or discharge the additional battery based at least in part on the additional profile. A time period of the additional cycle overlaps at least partially with a time period of the cycle of step 808, in some examples. In some examples, the step 818 includes initiating an additional discharge cycle to discharge an additional battery 106 into the battery 106 based at least on the charging parameter of the battery 106. For example, the battery 106a of FIG. 3 is discharged into the battery 306 to help the battery 306 meet the SoC specified by the charging parameter of the battery 306's profile. In some examples, the battery 106a includes a battery that is no longer fit for use for a particular application (e.g., the application of the battery 306 into which it is being discharged). In some examples, the battery 106a is associated with a discharge profile designed to help other batteries 306 meet their charge profile metrics.

In some examples, the method 800 includes assigning 820 the battery 106 and the additional battery 106 to a group. The method 800 includes determining 822 a group profile. The group profile includes a group parameter based at least in part on at least one of: a future condition of the battery, a future condition of the additional battery, an attribute of the additional battery, or any combination thereof. In some examples, the method includes determining 822 whether to override the profile with the group profile. In some examples, the method 800 includes initiating a new cycle and/or adjusting a current cycle in response to determining to override the profile of an individual battery 106 with the group profile.

In some examples, the method 800 includes receiving operational metrics from the device 424. The method 800 initiates a discharge cycle of a battery 106. The method 800 reads discharge battery data. The method 800 compares discharge battery data to the operational metric. The method 800 determines whether discharge battery data is within an acceptable deviation of the operational metric. If the discharge battery data is outside of the acceptable deviation, the method 800 adjusts the discharging (e.g., adjusts the ambient temperature, adjusts the discharge rate, etc.) and continues to read the discharge battery data. If the method 800 determines that the discharge battery data is within an acceptable deviation of the operational metric, the method 800 ends. In some examples, the method 800 is repeated at a specified frequency.

In some examples, a discharge profile includes a storage discharge profile. The storage discharge profile includes discharge metrics configured to bring the battery into a state acceptable for storage. For example, the discharge profile includes at least one of the following discharge metrics: maximum SoC, battery temperature, and/or any other discharge metrics to bring the battery to an acceptable SoC and/or temperature. In some examples, the storage discharge profile includes a final SoC metric of not less than 40% and not greater than 80%.

In some examples, a discharge profile includes a SoH measurement profile. The SoH measurement profile includes discharge metrics for measuring battery SoH based at least in part on measurements taken during the discharge cycle. In some examples, the discharge metrics for the SoH measurement profile are similar to and/or coincide with the simulation discharge metrics.

In some examples, a discharge profile of the battery 106a complements a charge profile of a load battery 306. The charge profile of the load battery 306 that the battery 106a is being discharged into includes charging metrics. The discharge profile of the battery 106a includes discharge metrics configured to match the charging metrics of the load battery 306's profile. For example, the load battery 306's charge profile includes a charging rate charge metric. The battery 106a's discharge profile includes a discharge rate to match the charging rate of the load battery 306.

In some examples, a discharge profile is a battery storage discharge profile. The battery storage discharge profile includes discharge parameters configured to bring the battery to an optimal storage state. For example, a parameter of a battery storage discharge profile includes a final SoC charging parameter of that is equal to or less than 45%.

In some examples, a discharge profile includes a battery ROI and/or a system ROI discharge profile. The battery ROI and system ROI include, for example, discharge parameters that correspond to the charging patterns described in connection with the battery ROI and system ROI charge parameters. For example, the discharge parameters include discharge rates, discharge schedules, etc. In some examples, the local processor 102 determines the discharge parameters based at least in part on a net benefit of discharging the battery 106a into another battery 306 (i.e., the benefits of charging the load battery 306).

In some examples, the battery discharge profile includes an environmental impact discharge profile. The environmental impact discharge profile includes discharge parameters configured to minimize adverse environmental impacts of discharging. The environmental impacts include, for example, adverse outcomes associated with needing to replace batteries 106. As such, in some examples, the environmental impact discharge profile includes discharge parameters configured to sustain long-term SoH of the battery 106. For example, an environmental impact discharge profile includes a final SoC discharge parameter that is between 20 and 80% to help sustain the battery and prolong the need for replacement.

In some examples, the discharge cycle module 624 is configured to initiate the battery discharge cycle while the battery 106 is received by the slot. For example, the discharge cycle module 624 instructs the communications board 103 to initiate the battery discharge cycle while the battery 106 is received by the slot 104. The communications board 103 activates a reverse flow of current out of the battery 106 to initiate the battery discharge cycle. For example, the communications board 103 activates a switch and/or instructs the charger board 105 to activate a switch connected to the power supply 107 to initiate the discharge cycle, directing current out of the battery 106 and into a load (e.g., load 230 of FIG. 2) to discharge the battery 106. The battery 106 remains in the slot 104 during the discharge cycle.

For example, as shown in FIG. 2, the charger board 105n discharges the battery 106n into a load, such as a conductor 230. The conductor 230 then transfers heat into an exhaust element. As another example, as shown in FIG. 3, the charger board 105a directs current from the battery 106a being discharged into another battery 306 to charge the other battery 406.

In some examples, the system 100 is configured to discharge the battery 106 down to a voltage level that is equivalent to a minimum level that is to be expected during operation of the battery 106 in the device 424. For example, the local processor 102 receives data from the device 424 indicating that the battery 106 was discharged down to a 20% SoC during a previous operation cycle. The communications board 103 initiates the discharge cycle for the battery 106 and reads the SoC of the battery 106 while discharging (e.g., from the BMS). In other examples, the charger board 105 transmits the SoC of the battery 106 to the communications board 103 during discharge. In some examples, the communications board 103 determines that the SoC of the battery is equal to, within an acceptable deviation of, or less than 20% and instructs the charger board 105 and/or the switch 124 to stop the discharge cycle. The charger board 105 and/or switch 124 stops the discharge cycle.

The charger board 105 and/or communications board 103 is configured to measure discharge battery data, or data relating to the battery 106 throughout the discharge cycle. For example, the discharge battery data includes at least one of: resistance of a cell 112, resistance of the battery 106, an output current of the battery, a temperature of the battery, a voltage of a cell 112 of the battery 106, and a battery 106 voltage. In some examples, reading the cell 112 resistance and/or battery 106 resistance involves temporarily pausing the discharge cycle to measure the resistance.

The communications board 103 transmits the discharge battery data and the charge battery data to a processor, such as the apparatus 600. The apparatus 600 is configured to determine, based at least in part on the charge battery data and on the discharge battery data, a SoH of the battery 106, a predicted degradation in SoH of the battery 106, and/or any combination thereof.

In some examples, the local processor 102 is configured to predict a degradation in SoH of the battery 106 for a particular operation. In some examples, the local processor 102 receives operational metrics for the future operation (e.g., ambient temperature, operation length, altitude, etc.) and initiates the one or more discharge cycles with parameters selected to mimic those operational metrics. Examples of the present disclosure include determining a change in SoH of the battery 106 over the discharge cycles and predicting a degradation in the SoH of the battery 106 for a future operation based at least in part on the determined change in SoH. In various examples, the local processor 102 is configured to predict a degradation in the SoH of the battery based at least in part on SoH measurements for that battery 106 over multiple discharge and/or operational cycles. In some examples, methods of the present disclosure include determining a safety rating for the battery 106 based at least in part on the SoH and/or SoH degradation.

FIG. 2 is a schematic diagram illustrating one example of a system 200 for discharging a battery 106 and determining a SoH of the battery 106. In some examples, during the discharge cycle, the system 200 directs current from the battery 106 to a load. For example, as shown in FIG. 2, the load is a conductor 230. For example, the conductor 230a, . . . , 230n is an uninsulated conductor, such as a dryer heating element. The conductor 230 is connected to an exhaust element 228.

Although FIG. 2 shows the conductor 230 within the slot 104n, examples of the present disclosure are not so limited. In some examples, the conductor 230 is outside of the slots 104 and, for example, below the slots 104. Multiple batteries 106 are connected to the same conductor 230.

As shown in FIG. 3, in some examples, the load is a second battery 406. The second battery 406 is within the same slot 104a as the battery 106a being discharged. As such, while the battery 106a is discharged, the second battery 406 is charged. For example, as shown in FIG. 3, the charger board 105 directs the current into the second battery 406. In some examples, the second battery 406 is located outside of the slot 104a. For example, the second battery 406 is located in a stack of batteries that each of the batteries 106 discharge into as a centralized load.

Although FIG. 3 shows a battery 106a being discharged into an additional battery 306 that is positioned within the slot 104a of the battery 106a, examples of the present disclosure are not so limited. In some examples, the slots 104 are arranged in vertical columns and/or horizontal rows. In such examples, batteries 106 in slots 104 of the same column each discharge into a battery positioned below or above the column. In some examples, the batteries 106 discharge into more than one battery. In some examples, each of the batteries 106 discharge into the same additional battery, and the additional battery serves as the power source 108 for the system 100.

In some examples, the battery 106 includes a battery pack with multiple cells 112a, 112b. Although FIG. 1 shows a battery 106 with only two cells 112a, 112b, examples of the present disclosure are not so limited. For example, batteries 106 include sixteen cells 112 each. In another example, at least one of the batteries 106 includes eight cells 112.

The batteries 106, in some examples, include both intelligent and unintelligent batteries. An intelligent battery 106a includes a battery management system (“BMS”) 118 that is configured to monitor parameters of the battery 106, provide data relating to the battery 106, etc. Examples of the present disclosure help to measure data from an unintelligent battery 106b during a charge and/or discharge cycle that may otherwise be measured and provided by a BMS 118 of an intelligent battery. In some examples, an unintelligent battery 106b includes an RFID chip 114b that is read by an RFID scanner 116b of a slot 104. For example, the RFID chip 114 stores data including at least one of: a serial number of the battery 106b, previous metrics of the battery 106b, or use of the battery 106b. In some examples, the RFID scanner 116 identifies a battery 106. In various examples, a charger board 105 measures data from the unintelligent battery 106b via wired connections to the unintelligent battery 106b.

In some examples, the battery 106 is an intelligent battery with a battery management system (“BMS”) 118a, . . . , 118n (referred to herein individually or collectively as “118”). The charger board 105 reads data from the BMS 118, and the communications board 103 is configured to receive data from the BMS 118. For example, the communications board 103 receives data directly from the BMS 118 via a wireless connection to the BMS 118.

In some examples, the charger board 105 is configured to connect to an unintelligent battery 106b (i.e., a battery 106b that does not have a BMS 118). The charger board 105b is configured to read data from the battery 106b that would otherwise be supplied by a BMS 118 if the battery 106b were an intelligent battery. The charger board 105 connects to the unintelligent battery 106b and is configured to perform coulomb counting, resistance measurements, and/or current measurements on the unintelligent battery 106b while the unintelligent battery 106b is within the slot 104 during a charge and/or discharge cycle. The charger board 105 then transmits this data to the communications board 103. The communications board 103 can adjust the charge and/or discharge cycle in similar manners as described herein in connection with intelligent batteries.

In some examples, the system 100 collects data from the battery 106 during the charge cycle and/or the discharge cycle. For example, at least one of the following collects data from the battery: the charger boards 105, communications boards 103, BMS 118, sensors within the batteries 106 and/or within the slots 104, and/or wired connections between the charger board 105 and the battery 106. In some examples, the system 100 uses this data to determine a SoH of the battery 106. For example, the local processor 102 and/or the remote server 122 determines the SoH of the battery 106. When the slot 104 receives the same battery 106, the system 100 performs a subsequent charge and/or discharge cycle and updates the SoH of the battery 106. Based on these SoH measurements, the local processor 102 and/or remote server 122 selects an appropriate action to take, such as, but not limited to: grouping the battery 106 with other batteries 106, adjusting charging rates of the battery 106, predicting a life expectancy of the battery 106, or any combination thereof. In some examples, the local processor 102 and/or remote server 122 determines to override a selected battery charge/discharge profile with a battery charge/discharge profile to optimize SoH. In one example, the system 100 is in the process of discharging the battery 106 based on a flight operations profile. However, upon determining that the SoH is below a threshold SoH, the local processor 102 overrides the flight operations discharge profile with a SoH preservation profile during the discharge cycle. As such, the system 100 dynamically adjusts the charging parameters during the discharge cycle.

In some examples, the communications board 103 and charger board 105 also receive information about at least one unintelligent battery via an RFID chip. For example, unintelligent battery 106b includes an RFID chip 114b. In some examples, each slot 104 includes an RFID scanner 116 configured to read data from the RFID chip 114 of the battery 106. The RFID scanner 116 is in communication with at least one of the communications board 103 and/or the charger board 105. In some examples, charger board 105 and/or communications board 103 are configured to read data from the batteries 106 via a wired connection. In some examples, a wired chip is attached to the battery 106 and connected to the charger board 105 and/or communications board 103. In some examples, the communications board 103 and/or the charger board 105 is configured to measure charge data and/or discharge data based at least in part on measurements from a wired connection to a battery 106 and/or battery cell 112. In some examples, the system 100 includes battery terminals and/or cell taps. For example, the system 100 includes a voltmeter connected to a particular cell tap for a certain cell 112 and configured to measure a voltage reading for that cell 112. The voltage reading can then be transmitted to the communications board 103 and/or the charger board 105. In various examples, the system 100 includes other devices for measuring conditions of the battery, such as a digital temperature sensor.

The communications boards 103 are configured to receive instructions and/or read data from at least one of: the charger boards 105, the local processor 102, the RFID scanners 116, the BMSs 118, the remote server 122, other devices connected to the network 120, or any combination thereof. The communications board 103 is also configured to transmit data and/or instructions to the charger board 105, the switch 124, and/or the power supply 107. The communications board 103 is configured to transmit data to at least one of the local processor 102, the display 110, the remote server 122, and/or any other device connected to the network 120. Although FIG. 1 shows the communications board 103 and the charger board 105 separately, examples of the present disclosure are not so limited. In some examples, the communications board 103 and charger board 105 share a circuit board and/or are part of the same circuit.

FIG. 1 shows both the communications board 103 and the charger board 105 positioned within the same slot 104. However, examples of the present disclosure are not so limited. In some examples, the communications board 103 and/or charger board 105 are positioned outside of the slot 104 but are still coupled, electrically and/or communicatively, to the battery 106. Additionally, FIG. 1 shows one communications board 103, one charger board 105, and one battery 106 per slot 104. However, examples of the present disclosure also include charging apparatuses 101 having multiple batteries 106 per slot, with one communications board 103 and one charger board 105 per battery 106.

In some examples, the communications board 103 receives, from a client device, remote server 122, and/or local processor 102, at least one of the following for a battery 106 received by a slot 104: a type corresponding to the battery, capacity, efficiency, minimum charge rate, maximum charge rate, operational metrics to be simulated during a discharge cycle, an acceptable deviation of a metric of the battery from an operational metric, an ideal temperature range, past SoH measurements, optimal battery groupings, past battery groupings, and/or any combination thereof.

In some examples, the communications board 103 transmits, to a client device, remote server 122, and/or local processor 102, a charging parameter and/or a discharging parameter for the battery 106. For example, the communications board 103 receives, at least one of the following for a battery 106 received by a slot 104: serial number, model, charge battery data, discharge battery data, or any combination thereof. In some examples, the communications board 103 also transmits, to a client device, remote server 122, and/or local processor 102 at least one of the following: a temperature of the charger board 105, a temperature within the slot 104, a temperature of the communications board 103, a serial number of the communications board, a temperature and/or humidity of an environment within the enclosure 1000, or any combination thereof.

The communications board 103 is configured to measure charge battery data of a charge cycle. In some examples, measuring charge battery data includes receiving charge battery data of a charge cycle. The communications board 103 receives the charge battery data, for example, via a wired or wireless connection to the charger board 105 of the battery slot 104 and/or via a wired or wireless communication connection to a battery management system (“BMS”) 118a of a battery 106a. The charge battery data includes, for example, at least one of: an input current of the battery 106, an output current of the battery 106, voltage of battery cells 112, resistance of battery cells 112, battery 106 resistance, battery 106 temperature, a capacity of the battery 106, a SoC of the battery 106, or any combination thereof. In some examples, the resistance measurements of the battery 106 and/or cells 112 include resistance measurements performed while the battery 106 is within the slot 104 but the charge and/or discharge cycle is paused. In some examples, the capacity of the battery 106 includes results of a coulomb counting process performed by the charger board 105.

In some examples, the communications board 103 also receives the battery serial number from at least one of the charger board 105, RFID scanner 116, BMS 118, or any combination thereof. As such, when the communications board 103 transmits the charge battery data and/or discharge battery data to the local processor 102 and/or remote server 122, that data is tied to a particular identifier for the battery 106.

In some examples, the communications board 103 receives information about the conditions within the slot 104 from the charger board 105. For example, the communications board 103 receives, from the charger board 105, at least one of the charger board's temperature and the charger board's humidity. In some examples, the charger board temperature and charger board humidity represent an ambient temperature and humidity within the slot 104.

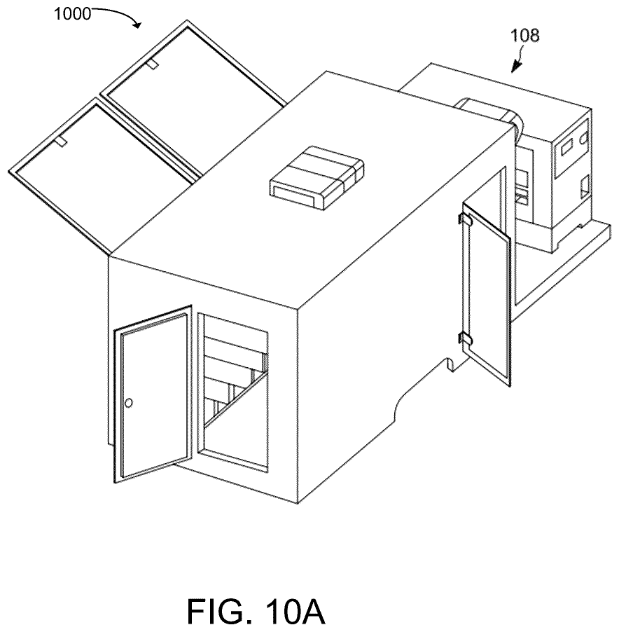

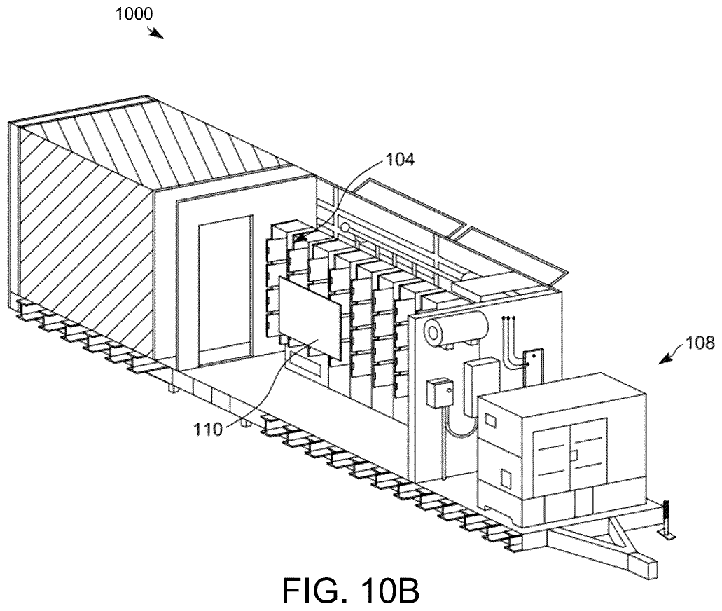

In some examples, the communications board 103 transmits the charge battery data to a processor. For example, the communications board 103 transmits data to a local processor 102. In some examples, the local processor 102 includes a local server, and the charging apparatus 101, communications board 103, and local processor 102 are all within the same enclosure (e.g., enclosure 1000 shown in FIGS. 10A-B). In some examples, the communications board 103 transmits data to a remote processor, such as to a remote server 122 via a network 120.

The network 120 includes at least one of: an Ethernet connection, the Internet, a local area network, a wide area network, and/or a wireless network. In some examples, the remote server 122 is connected to a number of client devices. The client devices include, for example, computing devices such as mobile communication devices and personal computers. The system 100 also includes applications accessed via the client devices. The functions described herein as being performed by the local processor 102 are, in some additional or alternative examples, performed by another processor communicatively connected to the communications board 103 via the network 120, such as the remote server 122, a client device, and/or any combination thereof. Each of the functions described herein as being performed by the local processor 102 through communication between the local processor 102 and other components of the system 100 may also be performed by the remote server 122 through communication between the remote server 122 and that component of the system 100.

In some examples, the communications board 103 instructs other components of the system 100 based on the charging parameters associated with the battery charge profile and/or the discharge parameters associated with the battery discharge profile. In some examples, the communications board 103 instructs the power supply 107 to initiate charge at a rate based on a charge rate parameter of the battery charge profile. In such examples, the power supply 107 initiates the flow of current to the battery 106 at a rate specified by the communications board 103.

FIG. 1 shows the local processor 102 is connected to a remote server 122 via a network 120. However, in some examples, the local processor 102 is not connected to any network 120 and thus is not connected to the remote server 122. In such examples, the local processor 102 is configured to perform the functions described herein as being performed by the remote server 122.

In some examples, the local processor 102 is a processor of a local server. In some examples, the local processor 102 is part of a computing device that is configured to collect and store data for a particular period. For example, the local server is configured to store the data, measurements, and/or calculations herein for a period of thirty-six days. After the period has passed, the memory of the computing device is wiped. In some examples, the computing device transmits the data, measurements, and calculations to another server, such as the remote server 122.

In some examples, the user inserts the battery 106 into the slot 104. For example, the user inserts the battery 106 into the slot 104 by opening a door of the slot 104. In some examples, the slot 104 includes the charger board 105, which connects to the battery 106 through cables and/or pins configured to read data from the battery 106, either directly or through a tether board. When the battery 106 is plugged in to the charger board 105 and/or the tether board, the charger board 105 detects that the battery 106 is present within the slot 104. In some examples, the charger board 105 and/or the communications board 103 activates an RFID scanner 116 of the slot 104 to scan the RFID tag 114 of the battery 106. In other examples, the communications board 103 and/or the charger board 105 receives a serial number from a BMS 118 of the battery 106.

Referring to FIG. 2, in some examples, each slot 104 includes a charger board 105. For example, the charger board 105 is built into the slot 104. The charger board 105 is connected to the power supply 107. The charger board 105 is configured to direct power to the battery 106 within the slot 104 to charge the battery 106 in a charge cycle. In some examples, the charger board 105 includes a circuit and/or a circuit board. In some examples, the charger board 105 is removable from the slot 104. The charger board 105 is exchangeable for a different charger board 105 to accommodate the battery 106. For example, each charger board 105 includes a quantity of inputs and/or switches, and the quantity corresponds to a quantity of cells 112 in the battery 106. In some examples, the charger board 105 is connected directly to the battery 106. In other examples, the battery 106 is electrically connected to a tether circuit board within the slot 104. In some examples, the battery 106 is mechanically connected (e.g., clipped) to the tether circuit board. In some examples, the tether circuit board connects the battery 106 to the charger board 105. In some examples, the charger board 105 is combined with and/or attached to the communications board 103.

In some examples, the charger board 105 is also configured to read data from the battery 106. For example, the charger board 105 reads at least one of the following for a battery 106: serial number, cell voltage, battery voltage, cell resistance, battery resistance, current, battery temperature, or any combination thereof. In some examples, the charger board 105 is configured to detect the presence of a battery 106 within the slot 104 (e.g., by determining that the charger board 105 and/or tether board has been connected to a battery 106) and, in response, transmit a message to the communications board 103. The communications board 103 then transmits the message to at least one of a local processor 102, display 110, and/or remote server 122. In some examples, the local processor 102 and/or the remote server 122 then instructs the communications board 103 to initiate the charge cycle. In other examples, the communications board 103 is configured to read data directly from the battery 106 without the charger board 105. Referring to FIG. 1, in some examples, the communications board 103 reads data from a BMS 118 of the battery 106. In some examples, the communications board 103 reads data from the battery 106 via one or more wired connections (e.g., cell taps and/or battery terminals) to the battery 106.

In some examples, the charger board 105 reads the battery 106's serial number from the battery 106. The communications board 103 reads the serial number from the charger board 105 and/or from the BMS 118 and transmits the serial number to the local processor 102. The local processor 102 provides the communications board 103 with charge and/or discharge cycle protocols for that battery. For example, the local processor 102 provides charge and/or discharge cycle protocols based at least in part on at least one of the following: another battery that the battery 106 is grouped with, parameters of a future operation planned for the device 424 and/or battery 106, past SoH measurements of the battery 106, charge and/or discharge cycle parameters received from a remote server 122, user input via a GUI of the display 110, a selected charging mode, and/or data from a past operational cycle of the battery 106.

In some examples, the charger board 105 and/or communications board 103 collects initial information about the battery 106 before a charge and/or discharge cycle. For example, the charger board 105 detects that the battery 106 is present and reads at least one of a SoC and/or a temperature of the battery 106. The charger board 105 then transmits this initial battery data to the communications board 103. In some examples, the communications board 103 transmits the initial battery data to the local processor 102.

In some examples, the charger board 105 is configured to determine whether the battery 106 is being charged according to the charging parameters specified by the charge profile. For example, the charger board 105 confirms that the rate of charge is at or below the charging rate of the battery charge profile. In response to determining that the rate of current flow is at or below that rate, the charger board 105 allows the current to flow through to the battery 106. If the charger board 105 determines that the rate of current flow from the power supply 107 is above the specified rate, the charger board 105 adjusts the rate of current flow to the battery 106 so as not to exceed the specified rate. In some examples, the charger board 105 is also configured to determine whether the battery 106 is being discharged according to discharge parameters specified by the communications board 103.

In some examples, the local processor 102 adjusts a parameter of the battery 106 prior to the charge cycle based at least in part on the initial battery data. For example, the local processor 102 determines, based on an initial temperature of the battery, that cooling is needed before starting the charge cycle. In response, the communications board 103 delays actuating the power supply 107 to begin a charge cycle until after a delay period has passed between cooling elements activating to cool the battery 106 and the beginning of the charge cycle. In another example, the processor 102 determines, based on battery's 106 temperature read from the slot 104 by the charger board 105, that the temperature of the battery 106 has come within an acceptable charging range. The processor 102 then initiates a charge cycle. In another example, the local processor 102 determines an goal charge rate for the charge cycle of the battery 106 based at least in part on the initial battery data and transmits that goal charge rate to the communications board 103.

In some examples, the local processor 102 automatically initiates charge and discharge cycles. For example, the local processor 102 initiates a charge cycle, discharge cycle, and another charge cycle daily such that the batteries 106 are charged to generate battery charge data and in preparation for a discharge cycle, discharged to generate battery discharge data, and charged in preparation for future use in a device 424.

In other examples, the local processor 102 initiates a charge cycle and a discharge cycle based on input from a user. For example, the local processor 102 receives an instruction from a user to initiate a charge and/or discharge cycle via a graphical user interface of the display 110 and/or a computing device (e.g., a mobile phone or a computer) connected to the processor 102 via the network. In such examples, the processor 102 is configured to request permission from the user to initiate a charge cycle and/or discharge cycle at a certain frequency. For example, if a charge cycle and/or discharge cycle has not been performed on a slot 104 in over twenty-four hours, the processor 102 sends a message to a user requesting permission to perform a charge, discharge, and subsequent charge cycle. If the user confirms, the processor 102 initiates the charge cycle.

The device 424 is a device 424 that is powered by replaceable batteries 106. In some examples, a first set of batteries 106 powers a device for a first operational cycle, and a different set of batteries 106 powers the device 424 for a subsequent operational cycle. For example, the device 424 is an aircraft, and the device 424 uses a first set of batteries 106 for a first flight and a second set of batteries 106 for a second flight while the first set is being charged by the charging apparatus 101.

In some examples, the RFID chip 114 and/or the BMS 118 is configured to store the battery charge and/or discharge profiles assigned to the battery 106. In other examples, battery charge and/or discharge profiles are associated with the serial number of the battery 106. A mobile application stores information related to each battery 106, organized by battery serial numbers. That information includes, for example, SoH measurements (both lifetime and instant), predicted life expectancy, assigned charge profiles, assigned discharge profiles, and/or any combination thereof. In some examples, the mobile application scans or receives a serial number of the battery from the user and displays the assigned charge/discharge profile to the user (e.g., “Battery Availability Profile”). In other examples, the charging apparatus 101 scans and/or reads the serial number of the battery 106 and displays the assigned charge/discharge profile on the display 110 of the charging apparatus 101. In some examples, the mobile application and/or the display 110 include a GUI configured to receive input from the user to change the assignment(s) of the charge profiles and/or the discharge profiles.

In some examples, the local processor 102 and/or remote server 122 updates a battery specifications profile based on a predicted life expectancy of the battery 106. The user can access the battery specifications profile, for example, through a mobile application and can view the predicted life expectancy. In some examples, the battery specifications profile is a report that includes at least one of the following: the predicted life expectancy, the most current SoH measurement, past SoH measurements, total time that the battery 106 has been in operation powering the device 424, optimal battery groupings, the quantity of charge cycles the battery 106 has been through, the quantity of discharge cycles the battery 106 has been through, or any combination thereof. In some examples, the battery specifications profile includes information about the charge and discharge cycles that the battery 106 has experienced. This includes, for example, a level of charge and/or discharge (i.e., change in SoC throughout the cycle), charge/discharge rate, total time of storage (e.g., storage within a charging apparatus), or any combination thereof.

In some examples, each of the slots 104 receives a power supply 107. In other examples, the power supply 107 is located outside of the slot 104 but still connected to the battery 106. Each of the power supplies 107 is powered by a power source 108 and is connected to a battery 106 to supply power to the battery 106 from the power source 108. Referring to FIG. 2, in some examples, the power supply 107 is connected to the battery 106 via a charger board 105. Referring to FIG. 1, in other examples, the power supply 107 is connected to the battery 106 directly and/or indirectly via a switch 124. In some examples, the switch 124 is communicatively coupled to and controllable by at least one of the communications board 103, the local processor 102, and/or the remote server 122.

In some examples, the power source 108 is a generator, but the system 100 includes a switch to turn the power source 108 off and a hookup to instead supply shore power to the power supplies 107.

FIG. 10A is an exterior view of an enclosure 1000 housing certain components of the system 100, such as the charging apparatus 101. As shown in FIG. 10A, the enclosure 1000 is, in some examples, positioned on a vehicle and/or on a mobile trailer. In such examples, components such as the power source 108, local processor 102, charging apparatus 101, charger boards 105, and communications boards 103, and power supplies 107 are portable. As shown in FIG. 10A, the power source 108 is positioned outside of the enclosure 1000, while the charging apparatus 101, charger boards 105, communications boards 103, and power supplies 107 are positioned within the enclosure 1000.

FIG. 10B is an interior view of the enclosure 1000. As shown in FIG. 10B, the enclosure 1000 includes a number of doors. The enclosure 1000 houses the slots 104, each of which include a door. The doors of the slots 104 are shown open in FIG. 10B. As shown in FIG. 10B, the display 110 is located proximate to the slots 104.

As described herein, in some examples, the system 100 includes remote computing devices, such as mobile computing devices. The remote computing devices are client devices connected to the network 120. In some examples, the remote computing devices are located outside of the enclosure 1000. The system 100 includes a mobile application accessed by the client device(s) through the network 120. In some examples, the system 100 also includes a web application to be accessed by the client device(s) through the network 120.

As shown in FIG. 10B, the slots 104 are stacked vertically. Each slot 104 includes a chamber with a door that opens and closes to receive the battery 106. In some examples, the slots 104 are made of a conductive material, such as metal. In some examples, the slots 104 are made of an insulating material.

Although FIG. 1 illustrates a single battery 106 within each slot 104, examples of the present disclosure are not so limited. In some examples, the slot 104 holds multiple batteries 106 simultaneously. For example, each slot 104 has a total volume of greater than 0.5 and less than 3 cubic feet. For example, the slot 104 has a total volume of approximately one cubic foot. In some examples, the slots 104 share walls. The slots 104 include small openings through which wires, such as communication cables and cables connecting each charger board 105 to the power supply 108, are fed.

Although not shown in FIGS. 1-12, in some examples, the slots 104 include cooling elements. For example, each slot 104 includes at least one of a fan or a hose. In some examples, the slot 104 includes an exhaust hose configured to exhaust air from a load used for the discharge cycle. In some examples, each slot 104 includes a number of ports. For example, the number of ports includes a cold air input port, a cold air output port, a hot air input port, and a hot air output port. Each port is connected to a valve that opens and closes the port. For example, each port is connected to a solenoid with a valve. The solenoid is in communication with the communications board 103 and is configured to be closed and/or opened based on instructions received from the communications board 103. For example, the communications board 103 and/or the processor 102 determines that a slot 104 needs to be cooled based on temperature sensors on the battery 106. In response, the cold air input solenoid opens its valve. In some examples, the processor 102 determines that hot air should flow into the slot 104 to simulate operational conditions during a discharge cycle. The communications board 103 transmits a signal to the hot air input solenoid to open its valve and/or a signal to the cold air input solenoid to close its valve.

Although not shown in FIG. 1, in some examples, the slot 104 includes a first section that receives the power supply 107 and a second section that receives the battery 106. For example, the slot 104 includes a wall between the first section and the second section, with an opening in the wall through which wires connecting the power supply 107 to the battery 106 are fed.

In some examples, the functions described in connection with the modules of the apparatus 500 and/or the modules of the apparatus 600 are preformed by different processors. For example, the functions described in connection with the battery grouping module 622 are performed by a remote server 122, whereas the functions described in connection with the profile module 504 and/or the charge cycle module 506 are performed by the local processor 102. In another example, the functions describe din connection with the profile module 504 are performed by the remote server 122 and/or a remote computing device, and the functions described in connection with the charge cycle module 506 are performed by the local processor 102.

The present invention may be embodied in other specific forms without departing from its spirit or essential characteristics. The described examples are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A method, comprising:
receiving a battery in a slot, wherein the battery is removable from the slot to power a device separate from the slot;
determining a profile for the battery, the profile comprising at least one of a charging parameter based at least in part on a charging priority for the battery, a discharging parameter based at least in part on a discharging priority for the battery, or a combination thereof; and
initiating at least one of:
a charge cycle to charge the battery based at least in part on the charging parameter while the battery is received by the slot; and
a discharge cycle to discharge the battery based at least in part on the discharging parameter while the battery is received by the slot.

2. The method of claim 1, further comprising:
receiving and/or determining a future condition for the battery; and
determining the profile further based at least in part on the future condition.

3. The method of claim 2, wherein:
the future condition comprises a future time of operation for the battery; and
the method further comprises:
receiving, during the charge cycle, a modification to the future time of operation; and
updating, during the charge cycle, the profile based at least in part on the modification.

4. The method of claim 3, wherein the future condition comprises a predicted operational condition of the battery and the method further comprises predicting the predicted operational condition of the battery based at least in part on at least one of the following: user input, a previous operational condition of the battery, or any combination thereof.

5. The method of claim 2, wherein the future condition comprises at least one of: a future time of operation of the battery, a characteristic of an additional battery selected to be grouped with the battery for future operation, a life expectancy of the battery, an end of a rental period for a charging apparatus comprising the slot, a predicted future cost of charging the battery, a predicted future return on investment of the battery, or any combination thereof.

6. The method of claim 1, further comprising determining the profile based at least in part on a characteristic of the battery, a characteristic of an additional battery grouped with the battery, or any combination thereof.

7. The method of claim 1, wherein determining the profile comprises selecting the profile from among one or more profiles.

8. The method of claim 1, further comprising reading data from the battery, wherein at least one of the charging parameter and the discharging parameter is further based on the data.

9. The method of claim 1, wherein the slot comprises a slot of a plurality of slots of a charging apparatus and the method further comprises:
determining an additional profile for an additional battery, the additional profile comprising at least one of an additional charging parameter, an additional discharging parameter, or a combination thereof; and
initiating at least one of:
an additional charge cycle to charge the additional battery based at least in part on the additional charging parameter while the additional battery is received by an additional slot of the plurality of slots; and
an additional discharge cycle to discharge the additional battery based at least in part on the additional discharging parameter while the additional battery is received by an additional slot of the plurality of slots.

10. The method of claim 9, wherein a time period of the at least one of the additional charge cycle and the additional discharge cycle at least partially overlaps a time period of the at least one of the charge cycle and the discharge cycle.

11. The method of claim 1, the charging parameter comprising at least one of: a rate of charge, a final state of charge, length of charge, charging schedule, length of time for the battery to be connected to the slot, ambient temperature of the slot, temperature of the battery, or any combination thereof.

12. The method of claim 1, further comprising:
assigning the battery and an additional battery to a group;
determining a group profile, the group profile comprising a group parameter based at least in part on at least one of: a future condition of the battery, a future condition of the additional battery, an attribute of the additional battery, or any combination thereof; and
determining whether to override the profile with the group profile;
initiating, in response to determining to override the profile with the group profile, at least one of:
an additional charge cycle to charge the battery based at least in part on the group parameter;
an additional discharge cycle to discharge the battery based at least in part on the group parameter;
an adjustment to the charge cycle to charge the battery based at least in part on the group parameter;
an adjustment to the discharge cycle to discharge the battery based at least in part on the group parameter; or
any combination thereof.

13. The method of claim 1, further comprising:
receiving information about the battery from a battery management system; and
determining, based at least in part on the information, at least one of: the profile, the charging parameter, the charging priority, the discharging parameter, the discharging priority, or any combination thereof.

14. The method of claim 1, further comprising initiating an additional discharge cycle to discharge an additional battery into the battery based at least in part on the charging parameter.

15. The method of claim 14, wherein:
the charging parameter comprises a goal state of charge (“SoC”) of the battery;
the method further comprises:
measuring an SoC of the battery; and
determining that the measured SoC is less than the goal SoC; and
initiating the additional discharge cycle to discharge the additional battery into the battery is in response to determining that the measured SoC is less than the goal SoC.

16. A system, comprising:
a slot configured to receive a battery, wherein the battery is removable from the slot to power a device, the device being separate from the slot;
a memory; and
a processor coupled with the memory and configured to cause the system to:
determine a profile for the battery, the profile comprising at least one of a charging parameter based at least in part on a charging priority for the battery, a discharging parameter based at least in part on a discharging priority for the battery, or a combination thereof; and
initiate at least one of:
a charge cycle to charge the battery based at least in part on the charging parameter while the battery is received by the slot; and
a discharge cycle to discharge the battery based at least in part on the discharging parameter while the battery is received by the slot.

17. The system of claim 16, at least one of the charging priority and the discharging priority comprising at least one of the following: long-term state of health (“SoH”) of the battery, battery performance, battery return on investment (“ROI”), ROI of the system, battery availability for use at a given time, compatibility with a source supplying power to a circuit used to initiate the at least one of the charge cycle and the discharge cycle, atmospheric emissions resulting from charging, atmospheric emissions resulting from discharging, or any combination thereof.

18. An apparatus, comprising:
a priorities module configured to determine and/or receive: a charging priority for a battery, a discharging priority for the battery, or a combination thereof;
a profile module configured to determine a profile for the battery, the profile comprising at least one of a charging parameter based at least in part on the charging priority for the battery, a discharging parameter based at least in part on the discharging priority for the battery, or a combination thereof; and
a charge cycle module configured to initiate at least one of:
a charge cycle to charge the battery based at least in part on the charging parameter while the battery is received by a slot from which the battery is removable to power a device separate from the slot; and
a discharge cycle to discharge the battery based at least in part on the discharging parameter while the battery is received by the slot,
wherein at least a portion of said modules comprise one or more of hardware circuits, programmable hardware circuits and executable code, the executable code stored on one or more computer readable storage media.

19. The apparatus of claim 18, wherein the profile module is further configured to:
predict a future operational condition for the battery; and
determine the discharging parameter to mimic the predicted future operational condition.

20. The apparatus of claim 18, the discharging parameter comprising at least one of: a discharge rate, a final state of charge, an environmental condition of the slot, a temperature of the battery, a discharge schedule, or any combination thereof.
